(19) United States
(12) Patent Application Publication
(10) Pub. No.: US 2025/0334882 A1
(43) Pub. Date: Oct. 30, 2025

(54) RESIST COMPOSITION AND PATTERN FORMATION METHOD USING THE SAME

(71) Applicant: Samsung Electronics Co., Ltd., Suwon-si (KR)

(72) Inventors: Minsang KIM, Suwon-si (KR); Hana KIM, Suwon-si (KR); Hyeran KIM, Suwon-si (KR); Sungan DO, Suwon-si (KR); Yonghoon MOON, Suwon-si (KR); Chanjae AHN, Suwon-si (KR); Changheon LEE, Suwon-si (KR); Kyuhyun IM, Suwon-si (KR); Aram JEON, Suwon-si (KR); Sungwon CHOI, Suwon-si (KR)

(73) Assignee: Samsung Electronics Co., Ltd., Suwon-si (KR)

(21) Appl. No.: 19/007,980

(22) Filed: Jan. 2, 2025

(30) Foreign Application Priority Data
Apr. 26, 2024 (KR) 10-2024-0056303

(51) Int. Cl. G03F 7/039

(52) U.S. Cl. CPC G03F 7/0392

(57) ABSTRACT

Provided are a resist composition including a polymer that includes a first repeating unit represented by Formula 1 and does not include a crosslinking group, and an additive represented by Formula 2, and a method of forming a pattern using the resist composition,

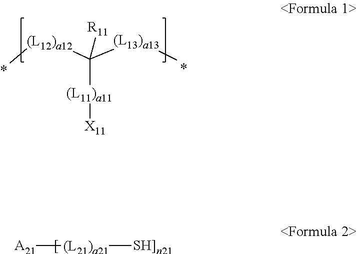

wherein descriptions of L₁₁ to L₁₃, a11 to a13, R₁₁, X₁₁, A₂₁, L₂₁, a21 and n21 in Formulae 1 and 2 are provided in the specification.

### CROSS-REFERENCE TO RELATED APPLICATION

This application is based on and claims priority under 35 U.S.C. § 119 to Korean Patent Application No. 10-2024-0056303, filed on Apr. 26, 2024, in the Korean Intellectual Property Office, the disclosure of which is incorporated by reference herein in its entirety.

### BACKGROUND

### 1. Field

The disclosure relates to a resist composition and/or a pattern formation method using the same.

### 2. Description of the Related Art

When manufacturing a semiconductor device, resists may have physical properties that change in response to light and resists may be used to form fine patterns. Among the resists, chemically amplified resists may be used. In chemically amplified resists, an acid may be formed through a reaction between light and a photoacid, and the acid may react with a base resin again to change the solubility of the base resin with respect to a developer, thereby enabling patterning.

In particular, when using high-energy rays with relatively high energy, such as EUV, the number of photons may be significantly small even when light of the same energy is irradiated. Accordingly, there may be a need for resist compositions capable of operating effectively even when used in small amounts, and capable of providing improved sensitivity, improved resolution, and/or reduced defects.

### SUMMARY

Provided are a resist composition having improved sensitivity, improved resolution, and/or reduced defects, and a pattern formation method using the same.

Additional aspects will be set forth in part in the description which follows and, in part, will be apparent from the description, or may be learned by practice of the presented embodiments of the disclosure.

According to an embodiment, a resist composition may include a polymer including a first repeating unit represented by Formula 1 and not including a crosslinking group, and an additive represented by Formula 2:

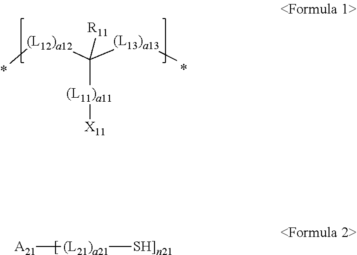

wherein, in Formulae 1 and 2,
L₁₁ to L₁₃ may each independently be a single bond, O, S, C(═O), C(═O)O, OC(═O), C(═O)NR₁₂, NR₁₂C(═O), S(═O), S(═O)₂, S(═O)₂O, OS(═O)₂, or a linear, branched, or cyclic C₁-C₃₀ divalent hydrocarbon group which optionally includes a heteroatom,
a11 to a13 may each independently be an integer from 1 to 4,
R₁₁ and R₁₂ may each independently be hydrogen, deuterium, a halogen; a cyano group, a hydroxyl group, an amino group, a carboxylic acid group, a thiol group, an ester moiety, a sulfonate ester moiety, a carbonate moiety, a lactone moiety, a sultone moiety, a carboxylic anhydride moiety, or a linear, branched, or cyclic C₁-C₃₀ monovalent hydrocarbon group which optionally includes a heteroatom,
X₁₁ may be an acid labile group,
A₂₁ may be a substituted or unsubstituted carbon atom, a substituted or unsubstituted C₁-C₃₀ alkyl group, a substituted or unsubstituted C₃-C₃₀ cycloalkyl group, a substituted or unsubstituted C₁-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₁-C₃₀ heterocycloalkenyl group, a substituted or unsubstituted C₂-C₃₀ alkynyl group, a substituted or unsubstituted C₁-C₃₀ aryl group, or a substituted or unsubstituted C₁-C₃₀ heteroaryl group,
when A₂₁ is the substituted or unsubstituted C₁-C₃₀ heterocycloalkyl group, the substituted or unsubstituted C₁-C₃₀ heterocycloalkenyl group, or the substituted or unsubstituted C₁-C₃₀ heteroaryl group, A₂₁ may not include nitrogen (N) or sulfur (S) as a ring source in the substituted or unsubstituted C₁-C₃₀ heterocycloalkyl group, the substituted or unsubstituted C₁-C₃₀ heterocycloalkenyl group, or the substituted or unsubstituted C₁-C₃₀ heteroaryl group,
L₂₁ may be a single bond, O, S, C(═O), C(═O)O, OC(═O), C(═O)NR₂₁, NR₂₁C(═O), S(═O), S(═O)₂, S(═O)₂O, OS(═O)₂, or a linear, branched, or cyclic C₁-C₃₀ divalent hydrocarbon group which optionally includes a heteroatom,
a21 may be an integer from 1 to 4,
R₂₁ may be hydrogen, deuterium, a halogen, a cyano group, a hydroxyl group, an amino group, a carboxylic acid group, a thiol group, an ester moiety, a sulfonate ester moiety, a carbonate moiety, a lactone moiety, a sultone moiety, a carboxylic anhydride moiety, or a linear, branched, or cyclic C₁-C₃₀ monovalent hydrocarbon group which optionally includes a heteroatom,
n21 may be an integer from 1 to 8, and
* is a bonding site with a neighboring atom.

According to an embodiment, a method of forming a pattern may include forming a resist film by applying the above-described resist composition onto a substrate; exposing at least a portion of the resist film to high-energy rays to provide an exposed resist film; and developing the exposed resist film using a developer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a pattern formation method according to an embodiment.

FIGS. 2A to 2C are side cross-sectional views illustrating a pattern formation method according to an embodiment.

FIGS. 3A to 3E are side cross-sectional views illustrating a method of forming a patterning structure, according to an embodiment.

FIGS. 4A to 4E are side cross-sectional views illustrating a method of forming a semiconductor device, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Since the disclosure can apply various transformations and can have various embodiments, specific embodiments will be illustrated in the drawings and described in detail in the detailed description. However, it should be understood that this is not intended to limit the disclosure to specific embodiments, and includes all transformations, equivalents, and substitutes included in the spirit and technical scope of the disclosure. In describing the disclosure, when it is determined that a specific description of known related arts unnecessarily obscures the gist of the disclosure, the detailed description thereof will be omitted.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of on/under/to the left/to the right in a non-contact manner.”

An expression used in the singular encompasses the expression of the plural unless it has a clearly different meaning in the context. Unless explicitly described to the contrary, it is to be understood that the terms “including,” “having,” and “comprising” are intended to indicate the existence of features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exit or may added.

Whenever a range of values is recited, the range includes all values that fall within the range as if expressly written, and the range further includes the boundaries of the range. Thus, a range of “X to Y” includes all values between X and Y and also includes X and Y.

The expression “Cr-Cy” used herein refers to the case where the number of carbons constituting a substituent is in a range of x to y. For example, the expression “C₁-C₆” refers to the case where the number of carbons constituting a substituent is in a range of 1 to 6, and the expression “C₆-C₂₀” refers to the case where the number of carbons constituting a substituent is in a range of 6 to 20.

The term “monovalent hydrocarbon group” used herein refers to a monovalent residue derived from an organic compound containing carbon and hydrogen or a derivative thereof, and specific examples thereof include linear or branched alkyl groups (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); monovalent saturated cyclic aliphatic hydrocarbon groups (cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and dicyclohexylmethyl group); monovalent unsaturated aliphatic hydrocarbon groups (an alkenyl group, an alkynyl group) (e.g., an allyl group); monovalent unsaturated cycloaliphatic hydrocarbon groups (a cycloalkenyl group) (e.g., a 3-cyclohexenyl); aryl groups (e.g., a phenyl group, a 1-naphthyl group, and a 2-naphthyl group); arylalkyl groups (e.g., a benzyl group and a diphenylmethyl group); heteroatom-containing monovalent hydrocarbon groups (e.g., a tetrahydrofuranyl group, a methoxymethyl group, an ethoxymethyl group, a methylthiomethyl group, an acetamidemethyl group, a trifluoroethyl group, (a 2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), or any combination thereof. In some embodiments, some of hydrogens in these groups may be replaced by a moiety including a heteroatom such as oxygen, sulfur, nitrogen, phosphorous or a halogen atom, or some of carbons in these groups may be replaced by a moiety including a heteroatom such as oxygen, sulfur, nitrogen, or phosphorus. Accordingly, these groups may include a hydroxyl group, a cyano group, a carbonyl group, a carboxyl group, an ether bond, an ester bond, a sulfonate ester bond, carbonates, a lactone ring, a sultone ring, a carboxylic anhydride moiety, or a haloalkyl moiety.

The term “divalent hydrocarbon group” as used herein refers to a divalent residue in which any one hydrogen of the monovalent hydrocarbon group is replaced with a bonding site with an adjacent atom. The divalent hydrocarbon group may include, for example, a linear or branched alkylene group, a cycloalkylene group, an alkenylene group, an alkynylene groups, a cycloalkylene group, an arylene groups, or a group in which some carbon atoms thereof are replaced with heteroatoms, and the like.

The term “alkyl group” as used herein refers to a linear or branched saturated aliphatic hydrocarbon monovalent group, and specific examples include a methyl group, an ethyl group, a propyl group, an isobutyl group, a sec-butyl group, a tert-butyl group, a pentyl group, an iso-amyl group, and a hexyl group, and the like. The term “alkylene group” as used herein refers to a linear or branched saturated aliphatic hydrocarbon divalent group, and specific examples thereof include a methylene group, an ethylene group, a propylene group, a butylene group, an isobutylene group, and the like.

The term “halogenated alkyl group” as used herein refers to a group in which one or more hydrogen atoms of an alkyl group are replaced with a halogen, and specific examples thereof include CF₃., and the like. The halogen atom may be F, Cl, Br, or I.

The term “alkoxy” as used herein refers to a monovalent group having a formula of —OA₁₀₁, where A₁₀₁ is an alkyl group. Specific examples thereof include a methoxy group, an ethoxy group, an isopropyloxy group, and the like.

The term “alkylthio group” as used herein refers to a monovalent group having a formula of SA₁₀₁, where A₁₀₁ is an alkyl group.

The term “halogenated alkoxy group” as used herein refers to a group in which one or more hydrogen atoms of an alkoxy group are replaced with a halogen atom, and specific examples thereof include —OCF₃ and the like.

The term “halogenated alkylthio group” as used herein refers to a group in which one or more hydrogen atoms s of an alkylthio group are replaced with a halogen atom, and specific examples thereof include —SCF₃ and the like.

The term “cycloalkyl group” as used herein refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group; and polycyclic condensed cyclic groups such as a norbornyl group and an adamantyl group. The term “cycloalkylene group” as used herein refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, and a dicyclohexylmethylene group.

The term “cycloalkoxy group” as used herein refers to a monovalent group having a formula of —OA₁₀₂, where A₁₀₂ is a cycloalkyl group. Specific examples thereof include a cyclopropoxy group, a cyclobutoxy group, and the like.

The term “cycloalkylthio group” as used herein refers to a monovalent group having a formula —SA₁₀₂, where A₁₀₂ is a cycloalkyl group.

The term “heterocycloalkyl group” as used herein may be a group in which some carbon atoms of the cycloalkyl group are replaced by a moiety including a heteroatom, such as oxygen, sulfur, or nitrogen, and the heterocycloalkyl group may include an ether bond, an ester bond, a sulfonate ester bond, carbonate, a lactone ring, a sultone ring, or carboxylic anhydride moiety. The term “heterocycloalkylene group” as used herein is a group in which some carbon atoms of the cycloalkylene group are replaced by a moiety containing a heteroatom, such as oxygen, sulfur, or nitrogen.

The term “heterocycloalkoxy group” as used herein refers to a monovalent group having a formula of —OA₁₀₃, where A₁₀₃ is a heterocycloalkyl group.

The term “alkenyl group” as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including one or more carbon-carbon double bonds.

The term “alkenyloxy group” as used herein refers to a monovalent group having a formula of —OA₁₀₄, where A₁₀₄ is an alkenyl group.

The term “cycloalkenyl group” as used herein refers to a monovalent unsaturated hydrocarbon cyclic group including one or more carbon-carbon double bonds. The term “cycloalkenylene group” as used herein refers to a divalent unsaturated hydrocarbon cyclic group including one or more carbon-carbon double bonds.

The term “cycloalkenyloxy group” as used herein refers to a monovalent group having a formula of —OA₁₀₅, where A₁₀₅ is a cycloalkenyl group.

The term “heterocycloalkenyl group” as used herein refers to a group in which some carbon atoms of the cycloalkenylene group are replaced by a moiety including a heteroatom, such as oxygen, sulfur, or nitrogen. The term “heterocycloalkenylene group” as used herein refers to a group in which some carbons of the cycloalkenylene group are replaced by a moiety including a heteroatom, such as oxygen, sulfur, or nitrogen.

The term “heterocycloalkenyloxy group” as used herein refers to a monovalent group having a formula of —OA₁₀₆, where A₁₀₆ is a heterocycloalkenyl group.

The term “alkynyl group” as used herein refers to a linear or branched unsaturated aliphatic hydrocarbon monovalent group including one or more carbon-carbon triple bonds.

The term “alkynyloxy group” as used herein refers to a monovalent group having a formula of —OA₁₀₇, where A₁₀₇ is an alkynyl group.

The term “aryl group” as used herein refers to a monovalent group having a carbocyclic aromatic system, and specific examples thereof include a phenyl group, a naphthyl group, an anthracenyl group, a phenanthrenyl group, a pyrenyl group, and chrysenyl group.

The term “aryloxy group” as used herein refers to a monovalent group having a formula of —OA₁₀₈, where A₁₀₈ is an aryl group.

The term “heteroaryl group” as used herein refers to a monovalent group having a heterocyclic aromatic system, and specific examples thereof include a pyridinyl group, a pyrimidinyl group, and a pyrazinyl group The term “heteroarylene group” as used herein refers to a divalent group having a heterocyclic aromatic system.

The term “heteroaryloxy group” as used herein refers to a monovalent group having a formula of —OA₁₀₉, where A₁₀₉ is a heteroaryl group.

The term “substituent” as used herein includes deuterium, a halogen atom, a hydroxyl group, a cyano group, a nitro group, a carbonyl group, a carboxylate group, an amino group, an ether moiety, ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cyclo alkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and C₁-C₂₀ heteroarylthio group, each substituted with deuterium, a halogen atom, a hydroxyl group, a cyano group, a nitro group, a carbonyl group, a carboxylate group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, or any combination thereof; and a combination thereof.

Hereinafter, example embodiments will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, embodiments set forth herein are merely examples and various changes may be made therein.

### [Resist Composition]

A resist composition according to an embodiment includes: a polymer including a first repeating unit represented by Formula 1 below and not including a crosslinking group; and an additive represented by Formula 2 below:

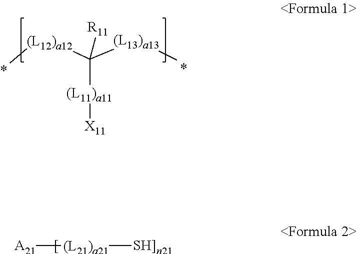

wherein, in Formulae 1 and 2,
L₁₁ to L₁₃ are each independently a single bond, O, S, C(═O), C(═O)O, OC(═O), C(═O)NR₁₂, NR₁₂C(═O), S(═O), S(═O)₂, S(═O)₂O, OS(═O)₂, or a linear, branched, or cyclic C₁-C₃₀ divalent hydrocarbon group which optionally includes a heteroatom,
a11 to a13 are each independently an integer from 1 to 4,
R₁₁ and R₁₂ are each independently hydrogen, deuterium, halogen; a cyano group, a hydroxyl group, an amino group, a carboxylate group, a thiol group, an ester moiety, a sulfonate ester moiety, a carbonate moiety, a lactone moiety, a sultone moiety, a carboxylic anhydride moiety, or a linear, branched, or cyclic C₁-C₃₀ monovalent hydrocarbon group which optionally includes a heteroatom,
X₁₁ is an acid labile group,
A₂₁ is a substituted or unsubstituted carbon atom, a substituted or unsubstituted C₁-C₃₀ alkyl group, a substituted or unsubstituted C₃-C₃₀ cycloalkyl group, a substituted or unsubstituted C₁-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₁-C₃₀ heterocycloalkenyl group, a substituted or unsubstituted C₂-C₃₀ alkynyl group, a substituted or unsubstituted C₁-C₃₀ aryl group, or a substituted or unsubstituted C₁-C₃₀ heteroaryl group,
when A₂₁ is the substituted or unsubstituted C₁-C₃₀ heterocycloalkyl group, the substituted or unsubstituted C₁-C₃₀ heterocycloalkenyl group, or the substituted or unsubstituted C₁-C₃₀ heteroaryl group, A₂₁ does not include nitrogen (N) or sulfur (S) as a ring source in the substituted or unsubstituted C₁-C₃₀ heterocycloalkyl group, the substituted or unsubstituted C₁-C₃₀ heterocycloalkenyl group, or the substituted or unsubstituted C₁-C₃₀ heteroaryl group,
L₂₁ is a single bond, O, S, C(═O), C(═O)O, OC(═O), C(═O)NR₂₁, NR₂₁C(═O), S(═O), S(═O)₂, S(═O)₂O, OS(═O)₂, or a linear, branched, or cyclic C₁-C₃₀ divalent hydrocarbon group which optionally includes a heteroatom,
a21 is an integer from 1 to 4,
R₂₁ is hydrogen, deuterium, halogen; a cyano group, a hydroxyl group, an amino group, a carboxylate group, a thiol group, an ester moiety, a sulfonic acid ester moiety, a carbonate moiety, a lactone moiety, a sultone moiety, a carboxylic anhydride moiety, or a linear, branched, or cyclic C₁-C₃₀ monovalent hydrocarbon group which optionally includes a heteroatom,
n21 is an integer from 1 to 8, and
* is a bonding site with a neighboring atom.

### <Polymer>

For example, in Formula 1, L₁₁ to L₁₃ may be each independently a single bond; O, S, C(═O), C(═O)O, OC(═O), C(═O)NH, NHC(═O), S(═O), S(═O)₂, S(═O)₂O, OS(═O)₂, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

As another example, in Formula 1, 11 to L₁₃ may be each independently selected from a single bond; O; S; C(═O); C(═O)O; OC(═O); C(═O)NH; NHC(═O); and a C₁-C₂₀ alkylene group, a C₃-C₂₀ cycloalkylene group, a C₃-C₂₀ heterocycloalkylene group, a C₂-C₂₀ alkenylene group, a C₃-C₂₀ cycloalkenylene group, a C₃-C₂₀ heterocycloalkenylene group, a C₆-C₂₀ arylene group, and a C₁-C₂₀ heteroarylene group, each unsubstituted or substituted with deuterium, a halogen, a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

As another example, in Formula 1, 11 to L₁₃ may be each independently selected from a single bond; O; S; C(═O); C(═O)O; OC(═O); C(═O)NH; NHC(═O); and a C₁-C₂₀ alkylene group, a C₃-C₂₀ cycloalkylene group, a C₃-C₂₀ heterocycloalkylene group, a phenylene group and a naphthylene group, each unsubstituted or substituted with deuterium, a halogen, a C₁-C₂₀ alkyl group, a C₁-C₂₀ halogenated alkyl group, a C₁-C₂₀ alkoxy group, a phenyl group, a naphthyl group, or any combination thereof.

In Formula 1, a11 to a13 respectively refer to the number of repetitions of L₁₁ to L₁₃.

For example, in Formula 1, a11 to a13 may each independently be an integer from 1 to 3.

As another example, in Formula 1, a11 to a13 may each independently be 1.

For example, in Formula 1, R₁₁ may be selected from hydrogen; deuterium; a halogen; a cyano group; a hydroxyl group; an amino group; a carboxylate group; a thiol group; and a C₁-C₂₀ alkyl group, a C₃-C₂₀ cycloalkyl group, and a C₆-C₂₀ aryl group, each unsubstituted or substituted with deuterium, a halogen, a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

As another example, in Formula 1, R₁₁ may be selected from hydrogen;
deuterium; a halogen; a cyano group; and a C₁-C₂₀ alkyl group unsubstituted or substituted with deuterium, a halogen, a cyano group, or any combination thereof.

As another example, in Formula 1, R₁₁ may be H, D, F, CH₃, CH₂F, CHF₂, CF₃, CH₂CH₃, CHFCH₃, CHFCH₂F, CHFCHF₂, CHFCF₃, CF₂CH₃, CF₂CH₂F, CF₂CHF₂, CF₂CF₃, Cl, CH₂C₁, CHCl₂, CCl₃, CHClCH₃, CHClCH₂Cl, CHClCHCl₂, CHClCCl₃, CCl₂CH₃, CCl₂CH₂Cl, CCl₂CHCl₂, or CCl₂CCl₃.

For example, in Formula 1, R₁₂ may be hydrogen, deuterium, a halogen, a cyano group, a hydroxyl group, an amino group, a carboxylate group, a thiol group, a C₁-C₂₀ alkyl group, a C₁-C₂₀ halogenated alkyl group, a C₃-C₂₀ cycloalkyl group, or a C₆-C₂₀ aryl group.

As used herein, the acid labile group refers to a group that is separated from the polymer by an acid to generate a polar group and acts to make the polymer more easily soluble in a developer, for example, an aqueous TMAH solution.

For example, the acid dissociation constant (pKa) of the acid labile group may be 13 or less, 3 to 13, or 5 to 10 (calculated value).

For example, in Formula 1, X₁₁ may include a group containing tertiary acyclic alkyl carbon, a group containing tertiary alicyclic carbon, or acetal.

As another example, in Formula 1, X₁₁ may be represented by any one of Formulae 6-1 to 6-12 below:

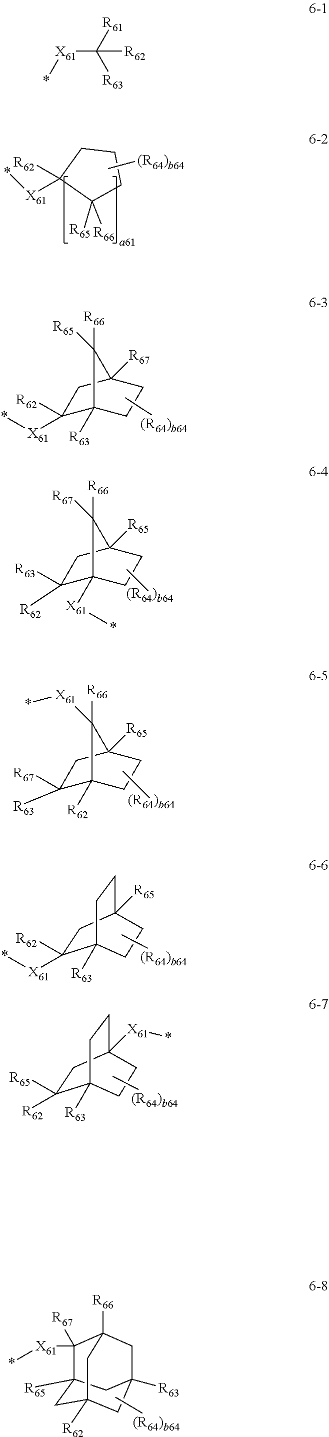

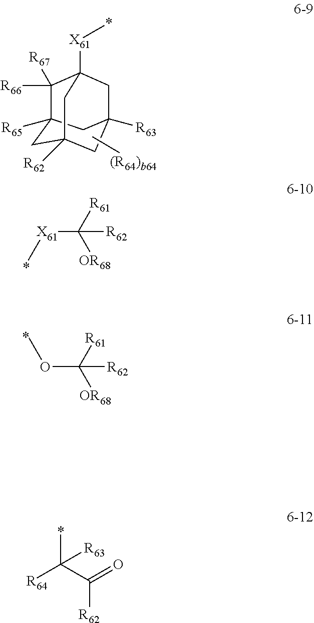

wherein, in Formulae 6-1 to 6-12,
X₆₁ is an ester moiety, a sulfonate moiety, a carbonate moiety, or a carbamate moiety;
a61 is an integer from 0 to 6,
R₆₁ and R₆₈ are each independently a linear, branched, or cyclic C₁-C₂₀ monovalent hydrocarbon group that optionally includes a heteroatom,
R₆₂ to R₆₇ are each independently hydrogen, deuterium, a halogen; a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, or a linear, branched, or cyclic C₁-C₃₀ monovalent hydrocarbon group which optionally incudes a heteroatom,
two adjacent groups of R₆₁ to R₆₈ are selectively combined with each other to form a ring,
b64 is an integer from 1 to 10, and
* is a bonding site with a neighboring atom.

In Formulae 6-1 to 6-12, X₆₁ may be an ester moiety or a carbonate moiety.

As another example, in Formula 1, X₁₁ may be represented by any one of Formulae 6-21 to 6-46 below:

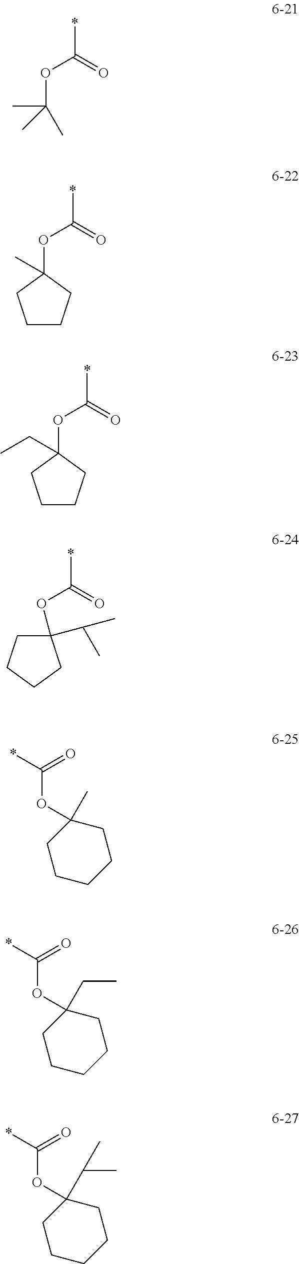

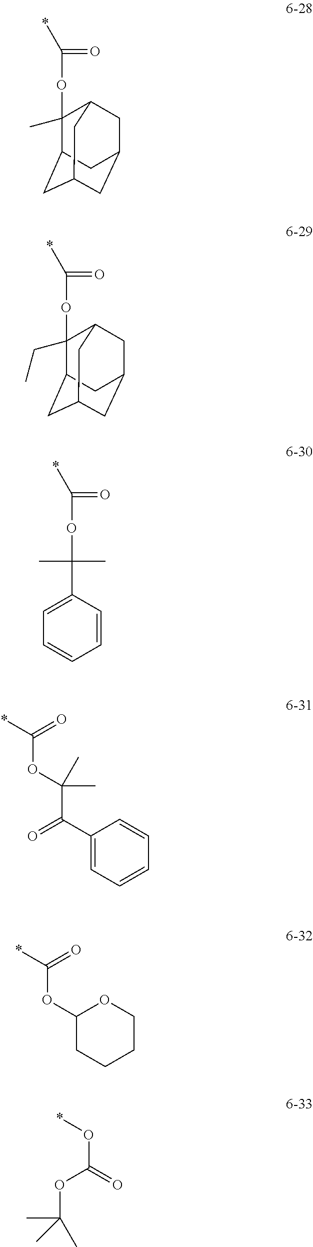

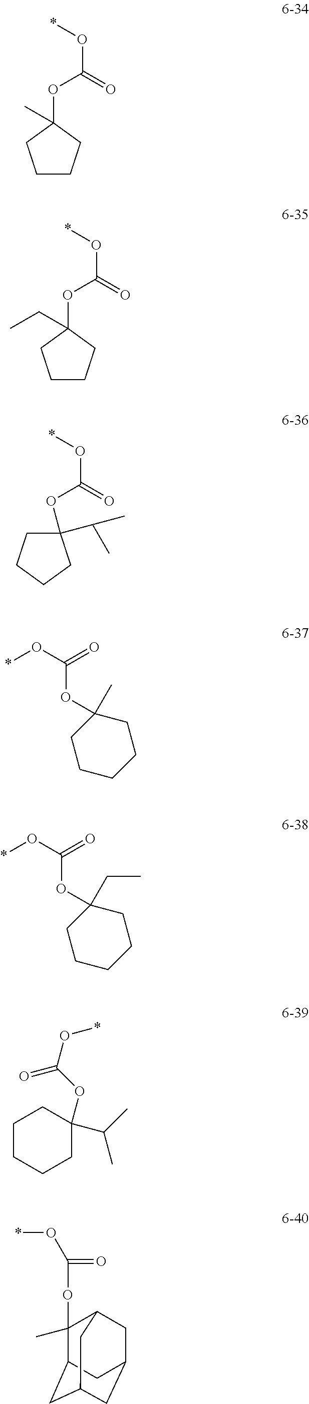

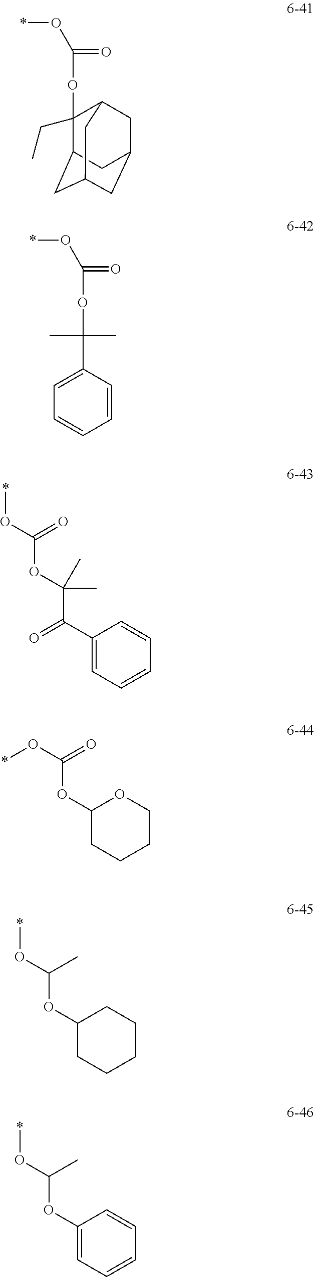

wherein, in Formulae 6-21 to 6-46,
* is a bonding site with a neighboring atom.

In an embodiment, the first repeating unit may be selected from Group I below:

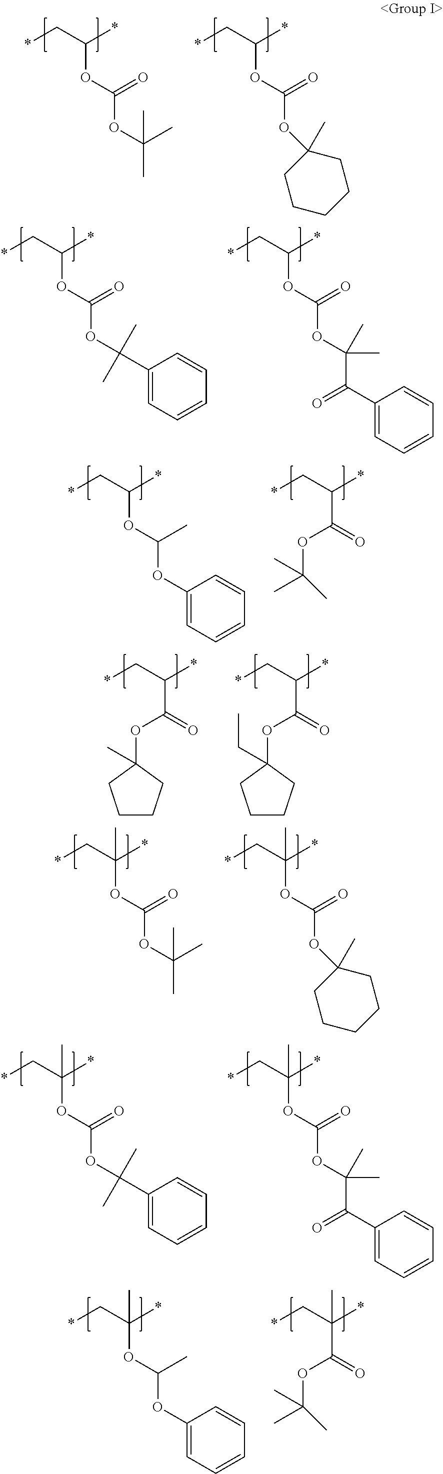

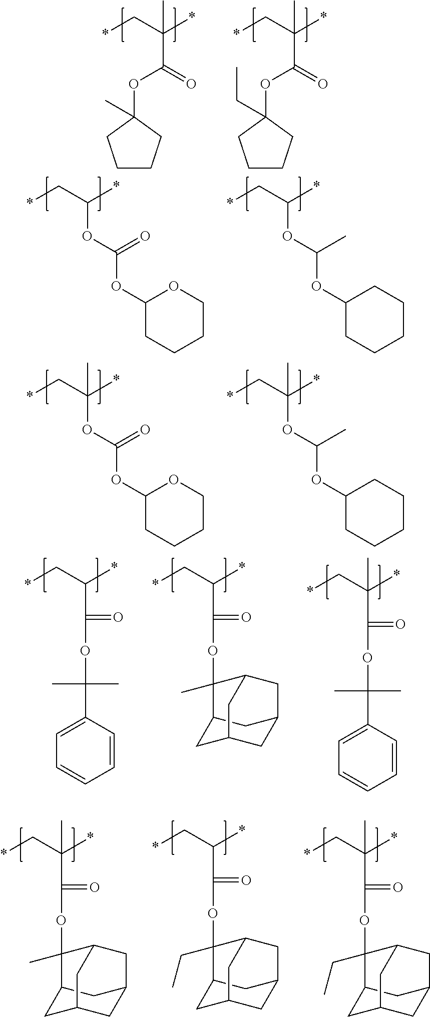

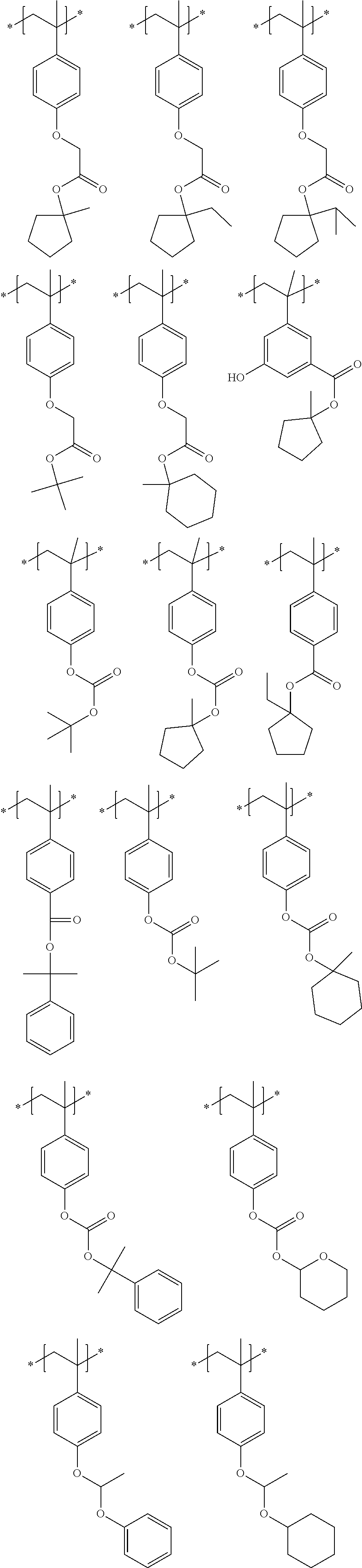

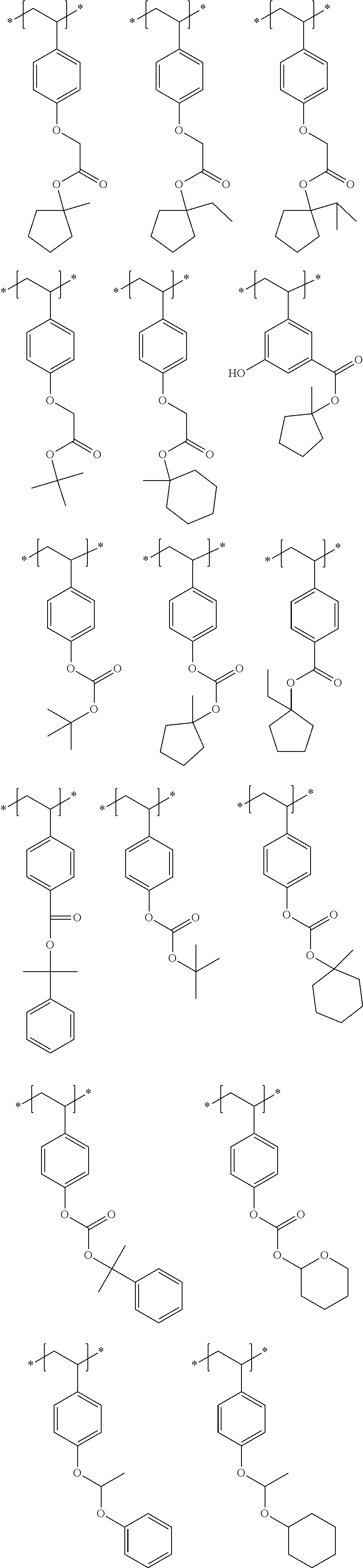

In an embodiment, the polymer may further include a second repeating unit represented by Formula 3 below:

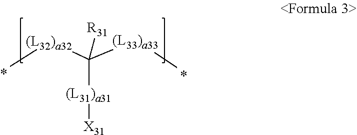

wherein, in Formula 3,
L₃₁ to L₃₃ are each independently a single bond, O, S, C(═O), C(═O)O, OC(═O), C(═O)NR₃₂, NR₃₂C(═O), S(═O), S(═O)₂, S(═O)₂O, OS(═O)₂, or a linear, branched, or cyclic C₁-C₃₀ divalent hydrocarbon group which optionally includes a heteroatom,
a31 to a33 are each independently an integer from 1 to 4,
R₃₁ and R₃₂ are each independently hydrogen, deuterium, a halogen, a cyano group, a hydroxyl group, an amino group, a carboxylate group, a thiol group, an ester moiety, a sulfonate ester moiety, a carbonate moiety, a lactone moiety, a sultone moiety, a carboxylic anhydride moiety, or a linear, branched, or cyclic C₁-C₃₀ monovalent hydrocarbon group which optionally includes a heteroatom,
X₃₁ is a non-acid labile group, and
* is a bonding site with a neighboring atom.

In Formula 3, L₃₁ to L₃₃ may be the same as the description of L₁₁ in Formula 1 above.

In Formula 3, a31 to a33 may be the same as the description of L₁₁ in Formula 1 above.

In Formula 3, R₃₁ may be the same as the description of R₁₁ in Formula 1 above.

In Formula 3, R₃₂ may be the same as the description of R₁₂ in Formula 1 above.

For example, in Formula 3, X₃₁ may be hydrogen; a halogen; a cyano group; a hydroxyl group; a carboxylate group; a thiol group; an amino group; or a C₁-C₃₀ linear, branched, or cyclic monovalent hydrocarbon group which optionally includes at least one polar moiety selected from a halogen, a cyano group, a hydroxyl group, a carboxylate group, a thiol group, O, C═O, C(═O)O, OC(═O), S(═O)O, OS(═O), a lactone moiety, a sultone moiety, and a carboxylic anhydride moiety.

As another example, in Formula 3, X₃₁ may be selected from hydrogen, a hydroxyl group, and groups represented by Formulae 5-1 to 5-16:

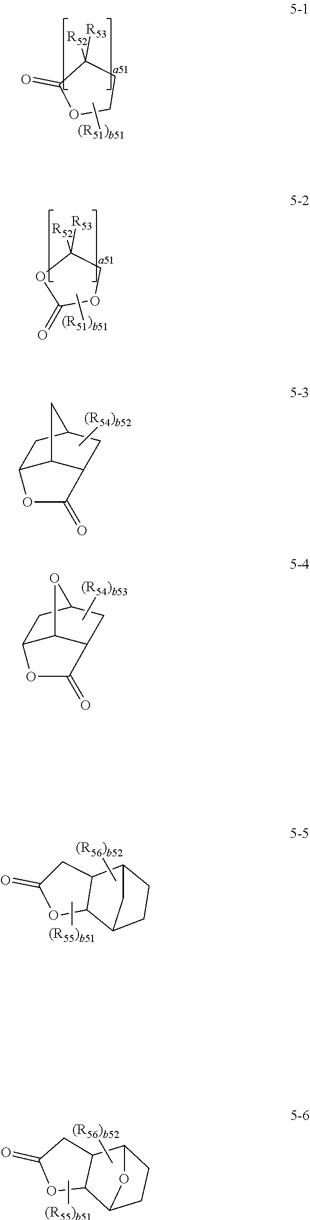

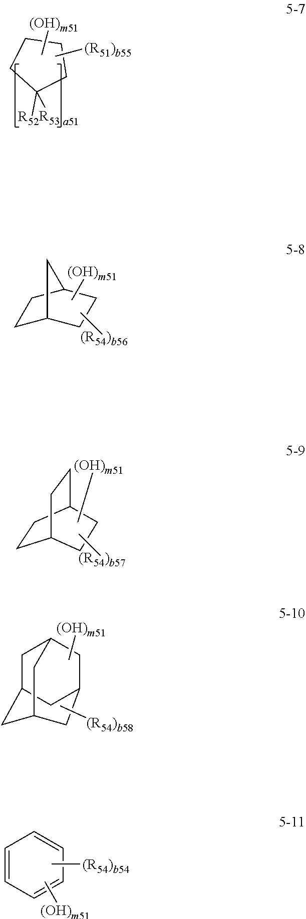

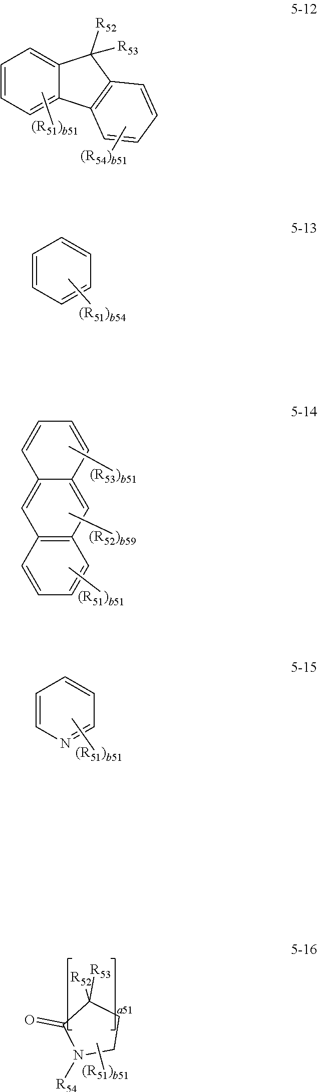

wherein, in Formulae 5-1 to 5-16,
a51 is 1 or 2,
R₅₁ to R₅₆ are each independently a bonding site with a neighboring atom, hydrogen, deuterium, a halogen, a cyano group, a hydroxyl group, an amino group, a carboxylate group, a thiol group, a carbonyl moiety, an ester moiety, a sulfonate moiety, a carbonate moiety, a carbamate moiety, a lactone moiety, a sultone moiety, a carboxylic anhydride moiety, or a linear, branched, or cyclic C₁-C₃₀ monovalent hydrocarbon group which optionally includes a heteroatom,
One of R₅₁ to R₅₃, one of R₅₄S and one of R₅₅ and R₅₆ is a bonding site with a neighboring atom,
b51 is an integer from 1 to 4,
b52 is an integer from 1 to 10,
b53 is an integer from 1 to 8,
b54 is an integer from 1 to 5,
b55 is an integer from 1 to 7,
b56 is an integer from 1 to 11,
b57 is an integer from 1 to 13,
b58 is an integer from 1 to 15,
b59 is an integer from 1 to 2, and
m51 is an integer from 1 to 4.

In Formula 3, X₃₁ may be selected from a hydroxyl group and the group represented by Formula 5-11.

In an embodiment, the second repeating unit may be selected from Group II below:

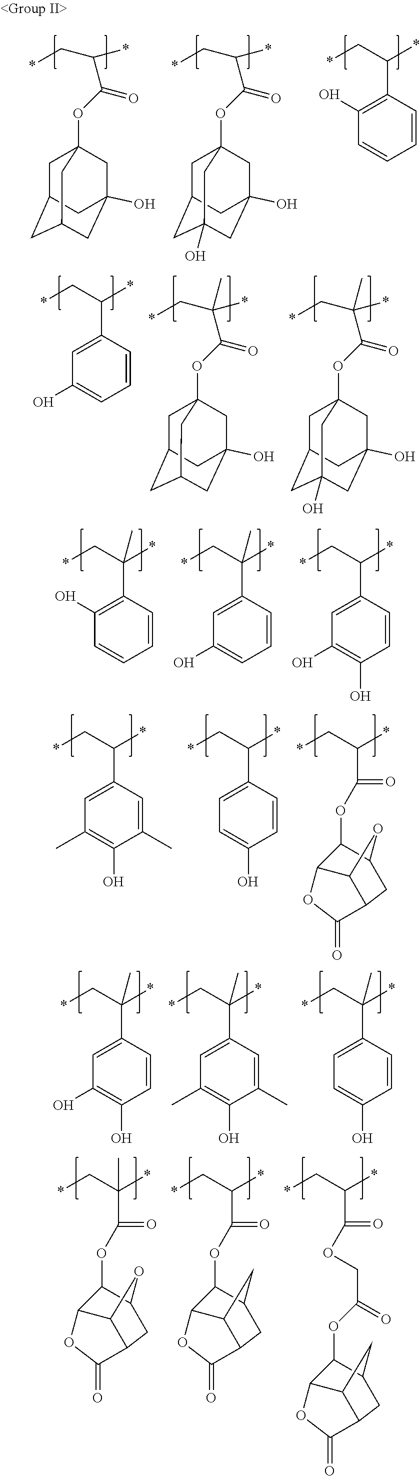

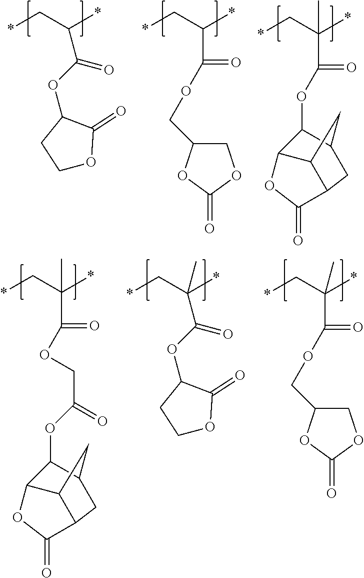

The crosslinking group may be an epoxy group or an oxetanyl group.

Since the polymer does not include a crosslinking group, crosslinking does not occur under heat, acid, and/or high-energy rays.

In an embodiment, the polymer may include the first repeating unit in an amount of about 1 mol % to about 100 mol %, about 5 mol % to about 100 mol %, or about 10 mol % to about 100 mol %.

For example, the polymer may consist of the first repeating unit.

As another example, the polymer may include the second repeating unit in an amount of about 0 mol % to about 99 mol %, about 1 mol % to about 99 mol %, or about 10 mol % to about 90 mol %.

In an embodiment, the polymer may consist of (or include) the first repeating unit and the second repeating unit. For example, the polymer may include the first repeating unit in an amount of about 1 mol % to about 99 mol % or about 10 mol % to about 90 mol %, and may include the second repeating unit in an amount of about 1 mol % to about 99 mol %, or about 10 mol % to about 90 mol %.

The polymer may have a weight average molecular weight (Mw) of about 1,000 to about 500,000, about 3,000 to about 100,000, or about 5,000 to about 50,000, which may be measured by gel permeation chromatography using a tetrahydrofuran solvent and polystyrene as standard materials.

The polymer may have a polydispersity index (PDI: Mw/Mn) of about 1.0 to about 3.0, or about 1.0 to about 2.5. When the above-described ranges are satisfied, the possibility of foreign substances remaining on a pattern may be reduced, or the deterioration of a pattern profile may be minimized. Accordingly, the resist composition may be more suitable for forming a fine pattern.

The polymer may be used alone or may be used as a mixture of two or more different types.

### <Additives>

For example, in Formula 2 above, A₂₁ may be a substituted or unsubstituted carbon atom, a substituted or unsubstituted C₁-C₃₀ alkyl group, a substituted or unsubstituted C₃-C₃₀ cycloalkyl group, a substituted or unsubstituted C₁-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₁-C₃₀ heterocycloalkenyl group, a substituted or unsubstituted C₂-C₃₀ alkynyl group, a substituted or unsubstituted C₁-C₃₀ aryl group, or a substituted or unsubstituted C₁-C₃₀ heteroaryl group, and
the C₁-C₃₀ heterocycloalkyl group, the C₁-C₃₀ heterocycloalkenyl group, and the C₁-C₃₀ heteroaryl group, each may include oxygen (O), selenium (Se), or phosphorus (P) as a heteroatom constituting a ring.

As another example, in Formula 2, A₂₁ may be a substituted or unsubstituted carbon atom, a substituted or unsubstituted C₁-C₃₀ alkyl group, a substituted or unsubstituted C₃-C₃₀ cycloalkyl group, a substituted or unsubstituted C₂-C₃₀ alkenyl group, a substituted or unsubstituted C₃-C₃₀ cycloalkenyl group, a substituted or unsubstituted C₂-C₃₀ alkynyl group, or a substituted or unsubstituted C₁-C₃₀ aryl group.

As another example, in Formula 2, A₂₁ may be a substituted or unsubstituted C₁-C₂₀ alkyl group or a substituted or unsubstituted C₃-C₂₀ cycloalkyl group.

In Formula 2, A₂₁ may be selected from a methyl group, an ethyl group, an n-propyl group, an iso-propyl group, an n-butyl group, an iso-butyl group, a sec-butyl group, a tert-butyl group, an n-pentyl group, an iso-pentyl group, a 2-methylbutyl group, a sec-pentyl group, a tert-pentyl group, a neo-pentyl group, a 3-pentyl group, a 3-methyl-2-butyl group, a cyclopentyl group, a cyclohexyl group, a cycloheptyl group, a phenyl group, and a naphthyl group, each which is unsubstituted or substituted with deuterium, a halogen, a cyano group, a hydroxyl group, an amino group, a carboxylate group, a thiol group, a methyl group, an ethyl group, an n-propyl group, an iso-propyl group, an n-butyl group, an iso-butyl group, a sec-butyl group, a tert-butyl group, a methoxy group, an ethoxy group, a cyclopentyl group, a cyclohexyl group, a phenyl group, or any combination thereof.

For example, in Formula 2, L₂₁ may be a single bond, O, C(═O), C(═O)O, OC(═O), a substituted or unsubstituted C₁-C₃₀ alkylene group, a substituted or unsubstituted C₃-C₃₀ cycloalkylene group, a substituted or unsubstituted C₂-C₃₀ alkenylene group, a substituted or unsubstituted C₃-C₃₀ cycloalkenylene group, or a substituted or unsubstituted C₆-C₃₀ arylene group.

As another example, in Formula 2, L₂₁ may be selected from a single bond; O; C(═O); C(═O)O; OC(═O); and a methylene group, an ethylene group, an n-propylene group, an n-butylene group, an iso-butylene group, a cyclopentylene group, and a cyclohexylene group, each which is unsubstituted or substituted with deuterium, a halogen, a cyano group, a hydroxyl group, an amino group, a carboxylic acid group, a thiol group, a methyl group, an ethyl group, an n-propyl group, an iso-propyl group, an n-butyl group, an iso-butyl group, a sec-butyl group, a tert-butyl group, a methoxy group, an ethoxy group, a cyclopentyl group, a cyclohexyl group, a phenyl group, or any combination thereof.

For example, in Formula 2, n21 may be an integer from 1 to 6.

As another example, in Formula 2, n21 may be an integer from 2 to 4.

In an embodiment, the additive may be selected from Group Ill below:

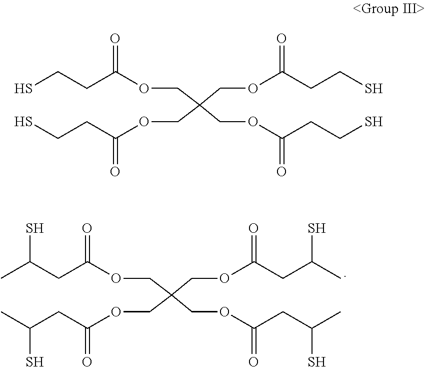 [SMILES: O=C(CCS)OCC(COC(=O)CCS)(COC(=O)CCS)COC(=O)CCS ; CC(S)CC(=O)OCC(COC(=O)CC(C)S)(COC(=O)CC(C)S)COC(=O)CC(C)S]

The additive may be included in an amount of about 0.01 parts by weight to about 50 parts by weight based on 100 parts by weight of the polymer. For example, the additive may be included in an amount of about 0.1 parts by weight to about 30 parts by weight based on 100 parts by weight of the polymer. When the above-described ranges are satisfied, acid can be produced at an appropriate level, and simultaneously, the formation of foreign particles due to any performance loss, such as reduction in sensitivity and/or lack of solubility, can be reduced.

When the resist composition includes a photoacid generator, the additive may be included in an amount of about 0.01 parts to about 70 parts by weight based on 100 parts by weight of the photoacid generator. In some embodiments, the additive may be included in an amount of 5 parts by weight to 60 parts by weight based on 100 parts by weight of the photoacid generator. When the above-described ranges are satisfied, the uniformity of a pattern can be improved, and the formation of foreign particles due to lack of solubility can be reduced.

Typically, since EUV (13.5 nm) has a lower photon number compared to an ArF immersion light source, as an exposure dose is lower, noise significantly increases in the boundary area between the area exposed by the EUV light source and the unexposed area. In the case of a lithography process using an EUV light source, in order to compensate for this, a larger amount of photoacid generator must be used compared to a lithography process using another light source with the same amount of light. However, when the resist composition includes a high content of a photoacid generator, the glass transition temperature (Tg) of the base resin may change, and thermal stability may decrease. Additionally, the resolution of resist patterns formed may be reduced due to the photoacid generator remaining during the lithography process using the EUV light source.

The resist composition may have properties such as improved developability and/or improved resolution.

The solubility of the resist composition in a developer is changed by exposure to high-energy rays. The resist composition may be a positive resist composition by which the exposed portions of a resist film are dissolved and removed to form a positive resist pattern, or may be a negative resist composition by which the unexposed portions of the resist film are dissolved and removed to form a negative resist pattern. In some embodiments, the resist composition may be a positive resist composition.

In addition, the resist composition according to an embodiment may be used for an alkaline development process using an alkaline developer in development processing when forming a resist pattern, or may be used for a solvent development process using a developer containing an organic solvent (hereinafter also referred to as an organic developer) in the development processing when forming a resist pattern.

Hereinafter, a photoacid generator, an organic solvent, a quencher, and any components contained as necessary will be described.

### <Photoacid Generator>

The photoacid generator may be any compound that can generate acid when exposed to high-energy rays, such as UV, DUV, EB, EUV, X-rays, α-rays, γ-rays, etc.

The photoacid generator may include a sulfonium salt, an iodonium salt, and a combination thereof.

In an embodiment, the photoacid generator may be represented by Formula 7 below:

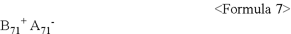

wherein, in Formula 7,
B₇₁_{⁺} is represented by Formula 7A below, A₇₁_{^{−}} is represented by any one of Formulae 7B to 7D below, and
B₇₁_{⁺} and A₇₁_{^{−}} may optionally be linked through a carbon-carbon covalent bond:

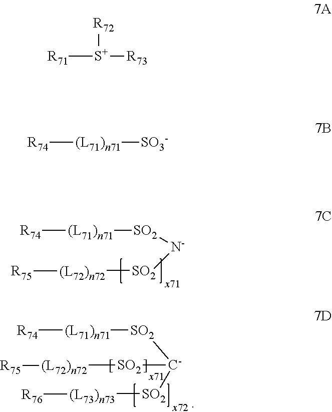

In Formulae 7A to 7D,
L₇₁ to L₇₃ are each independently a single bond or CRR′,
R and R′ are each independently hydrogen, deuterium, a halogen, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n71 to n73 are each independently 1, 2, or 3,
x71 and x72 are each independently 0 or 1,
R₇₁ to R₇₃ are each independently a C₁-C₃₀ linear, branched, or cyclic monovalent hydrocarbon group that optionally includes a heteroatom,
An adjacent two of R₇₁ to R₇₃ may be selectively combined with each other to form a condensation ring, and
R₇₄ to R₇₆ are each independently hydrogen, a halogen, or a C₁-C₃₀ linear, branched, or cyclic monovalent hydrocarbon group that optionally includes a heteroatom.

For example, in Formula 7, B₇₁_{⁺} may be represented by Formula 7A, and A₇₁_{^{−}} may be represented by Formula 7B. In Formula 7A, R₇₁ to R₇₃ may each be a phenyl group.

The photoacid generator may be included in an amount of 0.01 parts by weight to 40 parts by weight, 0.1 parts by weight to 40 parts by weight, or 0.1 parts by weight to 20 parts by weight based on 100 parts by weight of the polymer. When the above-described ranges are satisfied, appropriate resolution can be achieved, and problems related to foreign particles after development or during stripping can be reduced.

The photoacid generator may be used alone, or may be used as a mixture of two or more different types.

### <Organic Solvent>

The organic solvent contained in the resist composition is not particularly limited as long as it is capable of dissolving or dispersing amine compounds, polymers, photoacid generators, and optional component such as quenchers contained as necessary. The organic solvent may be used alone, or may be used as a combination of two or more different types. Additionally, a mixed solvent in which water and an organic solvent are mixed may be used.

Examples of the organic solvent may include an alcohol-based solvent, an ether-based solvent, a ketone-based solvent, an amide-based solvent, an ester-based solvent, a sulfoxide-based solvent, and a hydrocarbon-based solvent.

Examples of the alcohol-based solvent may include: monoalcohol-based solvents such as methanol, ethanol, n-propanol, isopropanol, 1-methoxy-2-propanol, 1-ethoxy-2-propanol, n-butanol, isobutanol, sec-butanol, tert-butanol, n-pentanol, isopentane ol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; polyhydric alcohol-based solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol; and polyhydric alcohol-containing ether-based solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, diethylene glycol dimethyl ether, propylene glycol monomethyl ether, propylene glycol dimethyl ether, propylene glycol monoethyl ether, propylene glycol monopropyl ether, propylene glycol monobutyl ether, dipropylene glycol monomethyl ether, dipropylene glycol monoethyl ether, and dipropylene glycol monopropyl ether.

Examples of the ether-based solvent may include dialkyl ether-based solvents such as diethyl ether, dipropyl ether, and dibutyl ether; cyclic ether-based solvents such as tetrahydrofuran and tetrahydropyran; and aromatic ring-containing ether-based solvents such as diphenyl ether and anisole.

Examples of the ketone-based solvent may include chain ketone-based solvents such as acetone, methyl ethyl ketone, methyl-n-propyl ketone, methyl-n-butyl ketone, methyl-n-pentyl ketone, diethyl ketone, methyl isobutyl ketone, 2-heptanone, ethyl-n-butyl ketone, methyl-n-hexyl ketone, diisobutyl ketone, and trimethylnonanone; cyclic ketone-based solvents such as cyclopentanone, cyclohexanone, cycloheptanone, cyclooctanone, and methylcyclohexanone; and 2,4-pentanedione, acetoin acetone, and acetophenone.

Examples of the amide-based solvent may include cyclic amide-based solvents such as N,N′-dimethylimidazolidinone and N-methyl-2-pyrrolidone; and chain amide-based solvents such as N-methylformamide, N,N-dimethylformamide, N,N-diethylformamide, acetamide, N-methylacetamide, N,N-dimethylacetamide, and N-methylpropionamide.

Examples of the ester-based solvent may include acetate ester-based solvents such as methyl acetate, ethyl acetate, n-propyl acetate, isopropyl acetate, n-butyl acetate, isobutyl acetate, sec-butyl acetate, T-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; ployhydric alcohol-containing ether carboxylate-based solvents such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, and dipropylene glycol monoethyl ether acetate; lactone-based solvents such as γ-butyrolactone and δ-valerolactone; carbonate-based solvents such as dimethyl carbonate, diethyl carbonate, ethylene carbonate, and propylene carbonate; lactate ester-bsed solvents such as methyl lactate, ethyl lactate, n-butyl lactate, and n-amyl lactate; and glycol diacetate, methoxytriglycol acetate, ethyl propionate, n-butyl propionate, isoamyl propionate, diethyl oxalate, di-n-butyl oxalate, methyl acetoacetate, ethyl acetoacetate, diethyl malonate, dimethyl phthalate, and diethyl phthalate.

Examples of the sulfoxide-based solvent may include dimethyl sulfoxide and diethyl sulfoxide.

Examples of the hydrocarbon-based solvent may include aliphatic hydrocarbon-based solvents such as n-pentane, isopentane, n-hexane, isohexane, n-heptane, isoheptane, 2,2,4-trimethyl pentane, n-octane, isooctane, cyclohexane, and methylcyclohexane; and aromatic hydrocarbon-based solvents such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, and n-amylnaphthalene.

The organic solvent may be selected from alcohol-based solvents, amide-based solvents, ester-based solvents, sulfoxide-based solvents, and any combinations thereof.

The organic solvent may be selected from propylene glycol monomethyl ether, propylene glycol monoethyl ether, propylene glycol monomethyl ether acetate, N-methyl-2-pyrrolidone, N,N-dimethylacetamide, ethyl lactate, dimethyl sulfoxide, and any combinations thereof.

On the other hand, when an acid labile group in the form of acetal is used, a high-boiling alcohol such as diethylene glycol, propylene glycol, glycerol, 1,4-butanediol, or 1,3-butanediol may be further added to the organic solvent to accelerate the deprotection reaction of acetal.

The organic solvent may be used in an amount of about 200 parts by weight to about 20,000 parts by weight or about 2,000 parts by weight to about 10,000 parts by weight, based on 100 parts by weight of the polymer.

### <Quencher>

The resist composition may further include a quencher.

The quencher may be a salt that generates an acid having a weaker acidity than the acid generated from the photoacid generator.

The quencher may include an ammonium salt, a sulfonium salt, an iodonium salt, and a combination thereof.

In an embodiment, the quencher may be represented by Formula 8 below:

B₈₁_{⁺}A₈₁_{^{−}} <Formula 8>
wherein, in Formula 8,
B₈₁_{⁺} is represented by any one of Formulae 8A to 8C, A₈₁_{^{−}} is represented by any one of Formulae 8D to 8F, and
B₈₁_{⁺} and A₈₁_{^{−}} are optionally linked through a carbon-carbon covalent bond:

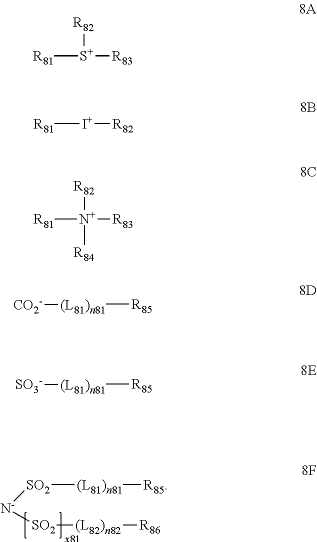

In Formulae 8A to 8C,
L₈₁ and L₈₂ are each independently a single bond or CRR′,
R and R′ are each independently hydrogen, deuterium, a halogen, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n81 and n82 are each independently 1, 2, or 3,
x81 is 0 or 1,
R₈₁ to R₈₄ are each independently a C₁-C₃₀ linear, branched, or cyclic monovalent hydrocarbon group which optionally includes a heteroatom,
Two adjacent ones of R₈₁ to R₈₄ may be selectively combined with each other to form a condensation ring,
R₈₅ and R₈₆ are each independently hydrogen; a halogen; or a C₁-C₃₀ linear, branched, or cyclic monovalent hydrocarbon group which optionally includes a heteroatom.

The quencher may be included in an amount of about 0 parts by weight to about 10 parts by weight, about 0.05 parts by weight to about 5 parts by weight, or about 0.1 parts by weight to about 3 parts by weight, based on 100 parts by weight of the polymer. When the above-described ranges are satisfied, appropriate resolution can be achieved, and problems related to foreign particles after development or during stripping can be reduced.

The quencher may be used alone, and may be used as a mixture of two or more different types.

### <Optional Components>

If necessary, the resist composition may further include a surfactant, a crosslinking agent, a leveling agent, a colorant, or any combination thereof.

The resist composition may further include a surfactant to improve applicability, developability, etc. Specific examples of the surfactant may include nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. As the surfactant, a commercially available product or a synthetic product may be used. Examples of the commercially available product of the surfactant may include KP341 (manufactured by Shin-Etsu Chemical Co., Ltd.), Polyflow No. 75, Polyflow No. 95 (above, manufactured by Kyoeisha Chemical Co., Ltd.), Ftop EF301, Ftop EF303, Ftop EF352 (above, manufactured by Mitsubishi Material Electronics Hwaseong Co., Ltd.), MEGAFACE® F171, MEGAFACE F173, R40, R41, R43 (above, manufactured by DIC Co., Ltd.), Fluorad® FC430, Fluorad FC431 (above, manufactured by 3M Co., Ltd.), AsahiGuard AG710 (manufactured by AGC Co., Ltd.), Surflon® S-382, Surflon SC-101, Surflon SC-102, Surflon SC-103, Surflon SC-104, Surflon SC-105, Surflon SC-106 (above, manufactured by AGC Semichemical Co., Ltd.).

The surfactant may be included in an amount of about 0 parts by weight to about 20 parts by weight based on 100 parts by weight of the polymer.

The surfactant may be used alone, and may be used as a mixture of two or more different types.

The method of producing the resist composition is not particularly limited, and for example, a method of mixing an amine compound, a polymer, a photoacid generator, and optional components added as necessary in an organic solvent may be used. The temperature or time during mixing is not particularly limited. If necessary, filtration may be performed after mixing.

### [Pattern Formation Method]

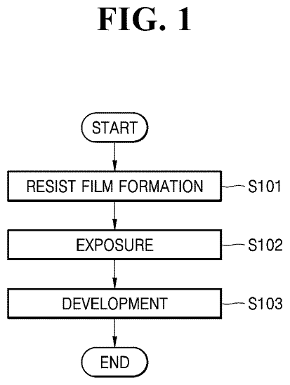

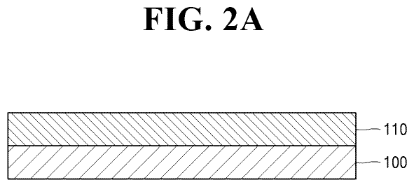

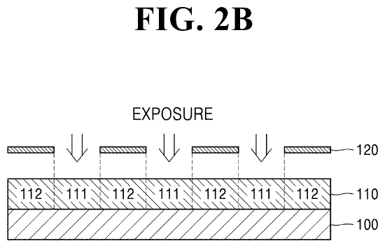

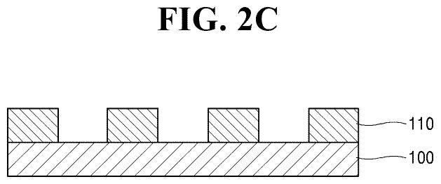

Hereinafter, a pattern formation method according to embodiments will be described in more detail with reference to FIGS. 1 and 2A to 2C. FIG. 1 is a flowchart illustrating a pattern formation method according to embodiments, and FIGS. 2A to 2C are each a side cross-sectional view illustrating a pattern formation method according to embodiments. Hereinafter, a pattern formation method using a positive resist composition will be described in detail by way of example, but example embodiments are not limited thereto.

Referring to FIG. 1, the pattern formation method includes a process S101 of applying a resist composition to form a resist film, a process S102 of exposing at least a portion of the resist film to high energy rays, and a process S103 of developing the exposed resist film using a developer. Such processes may be omitted or performed in a different order as needed.

First, a substrate 100 is prepared. As the substrate 100, for example, a semiconductor substrate such as a silicon substrate or a germanium substrate, a glass substrate, a quartz substrate, a ceramic substrate, a copper substrate, or the like may be used. In some embodiments, the substrate 100 may include a group III-V compound such as GaP, GaAs, or GaSb.

A resist composition according to example embodiments may be applied onto the substrate 100 to a desired thickness by a specific coating method to form a resist film 110. If necessary, the resist film 110 may be heated (referred to as pre-baked (PB) or post-anneal baked (PAB)) to remove an organic solvent remaining therein.

As the coating method, spin coating, dipping, roller coating, or other general coating methods may be used. Among these coating methods, in particular, spin coating may be used, and the viscosity, concentration and/or spin speed of the resist composition may be controlled to form the resist film 110 having a desired thickness. The resist film 110 may have a thickness of about 10 nm to about 300 nm. In some embodiments, the resist film 110 may have a thickness of about 30 nm to about 200 nm.

The lower limit of the temperature of PB may be 60° C. or more, or 80° C. or more. Additionally, the upper limit of the temperature of PB may be 150° C. or less, or 140° C. or less. The lower limit of the time of PB may be 5 seconds or more, or 10 seconds or more. The upper limit of the time of PB may be 600 seconds or less, or 300 seconds or less.

Before applying the resist composition to the substrate 100, an etching target film (not shown) may be further formed on the substrate 100. The etching target film may refer to a layer on which an image is transferred from a resist pattern and converted into a certain pattern. In an embodiment, the etching target film may be formed to include an insulating material such as silicon oxide, silicon nitride, or silicon oxynitride. In some embodiments, the etching target film may be formed to include a conductive material such as metal, metal nitride, metal silicide, or a metal silicide nitride. In some embodiments, the etching target film may be formed to include a semiconductor material such as polysilicon.

In an embodiment, an antireflection film may be further formed on the substrate 100 to improve and/or maximize the efficiency of a resist. The antireflection film may be an organic or inorganic antireflection film.

In an embodiment, a protective film may be further provided on the resist film 100 to reduce the influence of alkaline impurities included during a process. Additionally, when immersion exposure is performed, for example, a protective film for immersion may also be provided on the resist film 100 to avoid direct contact between an immersion medium and the resist film 100.

Next, at least a portion of the resist film 110 may be exposed to high energy rays. For example, high-energy rays passing through a mask 120 may be irradiated to at least a portion of the resist film 110. For this reason, the resist film 110 may have an exposed portion 111 and an unexposed portion 112.

During the exposure process, if the resist composition includes an amine compound, the amine compound may be ionized to generate radical cations and electrons.

In some cases, this exposure is performed by applying high energy rays through a mask having a certain pattern using a liquid such as water as a medium. Examples of the high energy rays may include ultraviolet (UV) rays; deep ultraviolet (DUV) rays; extreme ultraviolet (EUV) rays (wavelength 13.5 nm); electromagnetic waves such as X-rays and γ-rays; electron beams (EBs); and charged particle rays such as α-rays.

Irradiation of these high-energy rays may be collectively referred to as “exposure.”

As an exposure light source, various light sources, for example, a light source emitting laser beams in the UV range, such as a KrF excimer laser (wavelength of 248 nm), an ArF excimer laser (wavelength of 193 nm), and an F2 excimer laser (wavelength of 157 nm), a light source emitting harmonic laser beams in the far ultraviolet or vacuum violet range by converting wavelengths of laser beams received from a solid laser light source (YAG or semiconductor laser), and a light source emitting EBs or EUVs may be used. During exposure, the exposure may be usually performed through a mask corresponding to a desired pattern, but when the exposure light source is an electron beam, the exposure may be performed directly by drawing without using a mask.

An integral dose of high energy rays, for example, when ultraviolet rays are used as the high energy rays, may be 2000 mJ/cm² or less, or 500 mJ/cm² or less. In addition, when EBs are used as the high energy rays, the integral dose may be 5000 pC/cm² or 1000 pC/cm² or less.

In addition, post exposure bake (PEB) may be performed after the exposure. The lower limit of the temperature of PEB may be 50° C. or more, or 80° C. or more. The upper limit of the temperature of PEB may be 180° C. or less, or 130° C. or less. The lower limit of the time of PEB may be 5 seconds or more, or, 10 seconds or more. The upper limit of the time of PEB may be 600 seconds or less, or 300 seconds or less.

Next, the exposed resist film 110 may be developed using a developer. The exposed portion 111 may be washed away by the developer, and the unexposed portion 112 may remain without being washed away by the developer.

Examples of the developer may include an alkaline developer and a developer containing an organic solvent (hereinafter also referred to as “organic developer”). Examples of a developing method may include a dipping method, a puddle method, a spray method, and a dynamic injection method. A developing temperature may be, for example, about 5° C. or more and about 60° C. or less, and a developing time may be, for example, about 5 seconds or more and about 300 seconds or less.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanol amine, tetramethyl ammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

A lower limit of an amount of the alkaline compound included in the alkaline developer may be 0.1 wt % or more, 0.5 wt % or more, or 1 wt % or more. In addition, an upper limit of the amount of the alkaline compound included in the alkaline developer may be 20 wt % or less, 10 wt % or less, or 5 wt % or less.

After development, the resist pattern may be washed with ultrapure water, and then water remaining on the substrate and pattern may be removed.

As the organic solvent included in the organic developer, for example, the same organic solvents as those described in the part of <Organic Solvent> of [Resist Composition] may be used.

A lower limit of the amount of the organic solvent in the organic developer may be 80 wt % or more, 90 wt % or more, 95 wt % or more, or 99 wt % or more.

The organic developer may also include a surfactant. In addition, the organic developer may also include a trace amount of water. Additionally, during development, the development may be stopped by substituting with a different type of solvent from the organic developer.

The resist pattern after the development may be further cleaned. Ultrapure water, rinse solution, or the like may be used as a cleaning solution. The rinse solution is not particularly limited as long as it does not dissolve a resist pattern, and a solution including a general organic solvent may be used. For example, the rinse solution may be an alcohol-based solvent or an ester-based solvent. After cleaning, the rinse solution remaining on the substrate and pattern may be removed. In addition, when ultrapure water is used, water remaining on the substrate and pattern may be removed.

In addition, the developer may be used alone or in combination of two or more types.

After the resist pattern is formed as described above, a pattern interconnection substrate may be obtained by etching. The etching may be performed by known methods such as dry etching using plasma gas and wet etching using an alkaline solution, a copper (II) chloride solution, an iron (II) chloride solution, or the like.

After the resist pattern is formed, plating may be performed. The plating method is not particularly limited, and examples of thereof may include copper plating, solder plating, nickel plating, and gold plating.

The resist pattern remaining after the etching may be peeled off with an organic solvent. Examples of such an organic solvent may include, but are not particularly limited to, propylene glycol monomethyl ether acetate (PGMEA), propylene glycol monomethyl ether (PGME), and ethyl lactate (EL). The peeling method is not particularly limited, and examples thereof may include an immersion method and a spray method. Additionally, the interconnection substrate on which the resist pattern is formed may be a multilayer interconnection substrate, and may have small-diameter through-holes.

In an embodiment, the interconnection substrate may be formed by a method of forming a resist pattern, depositing metal in a vacuum, and then dissolving the resist pattern in a solution, that is, a lift-off method.

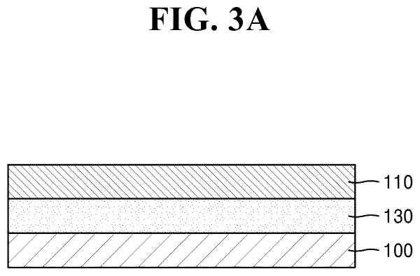

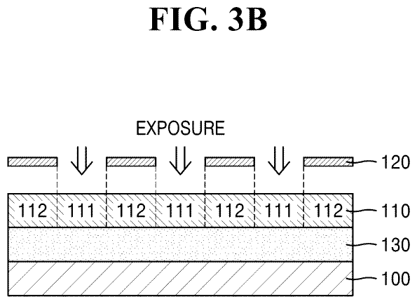

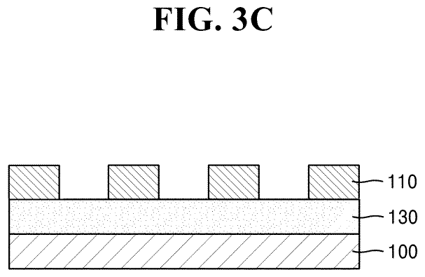

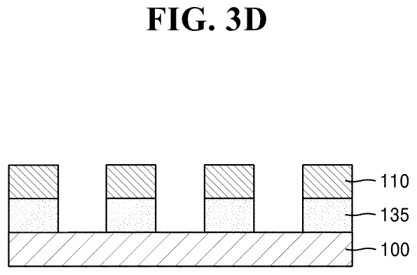

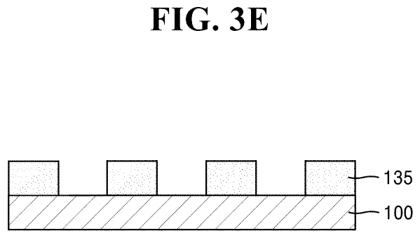

FIGS. 3A to 3E are side cross-sectional views illustrating a method of forming a patterning structure according to an embodiment.

As shown in FIG. 3A, a material layer 130 may be formed on the substrate 100 before forming the resist film 110 on the substrate 100. The resist film 110 may be formed on the material layer 130. The material layer 130 may include an insulating material (for example, silicon oxide, silicon nitride), a semiconductor material (for example, silicon), or a metal (for example, copper). In some embodiments, the material layer 130 may have a multi-layer structure. The material of the material layer 130 may be different from the material of the substrate 100.

As shown in FIG. 3B, the resist film 110 may undergo a pre-exposure bake process and be exposed to high-energy rays through the mask 120, and then the resist film 110 may include an exposed portion 111 and an unexposed portion 112.

As shown in FIG. 3C, the exposed resist film 110 may be developed using a developer. The exposed portion 111 may be washed away by the developer, and the unexposed portion 112 may remain without being washed away by the developer.

As shown in FIG. 3D, the exposed portion of the material layer 130 may be etched by using the resist pattern 110 as a mask to form a material pattern 135 on the substrate 100.

As shown in FIG. 3E, the resist pattern 110 may be removed.

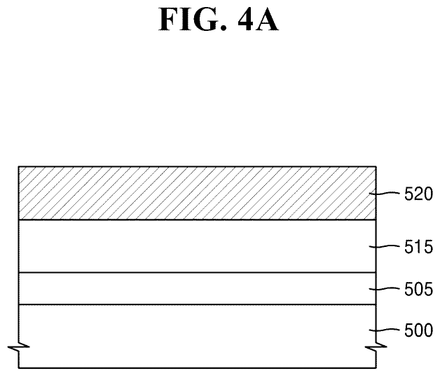

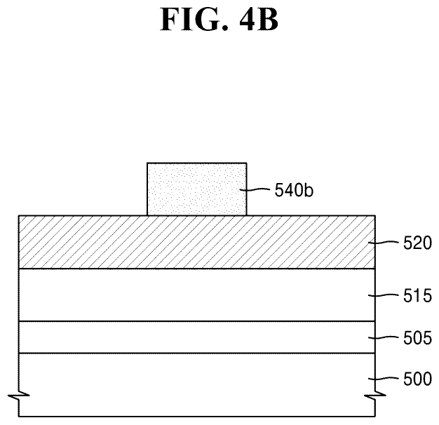

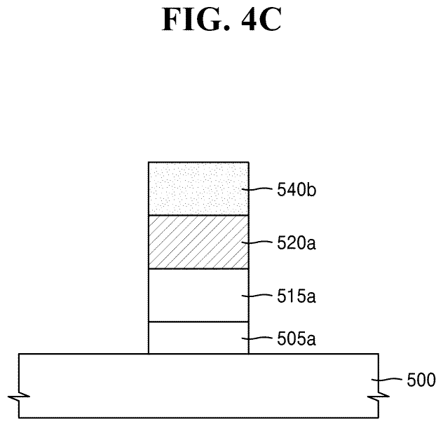

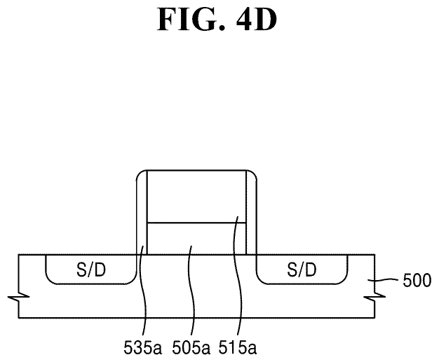

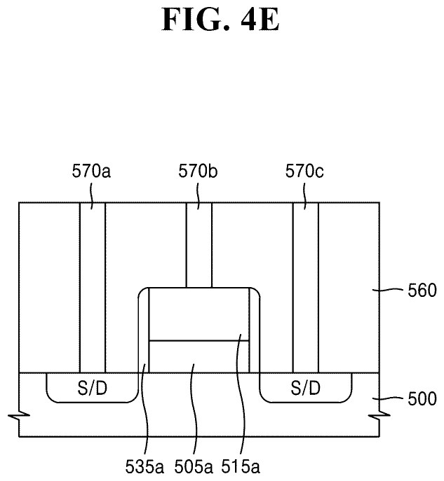

FIGS. 4A to 4E are side cross-sectional views showing a method of forming a semiconductor device according to an embodiment.

As shown in FIG. 4A, a gate dielectric 505 (for example, silicon oxide) may be formed on a substrate 500. The substrate 500 may be a semiconductor substrate such as a silicon substrate. A gate layer 515 (for example, doped polysilicon) may be formed on the gate dielectric 505. A hard mask layer 520 may be formed on the gate layer 515.

As shown in FIG. 4B, a resist pattern 540b may be formed on the hard mask layer 520. The resist pattern 540b may be formed using a resist composition according to an embodiment. The resist composition may include an organic solvent.

As shown in FIG. 4C, the gate layer 515 and the gate dielectric 505 may be etched to form a hard mask pattern 520a, a gate electrode pattern 515a, and a gate dielectric pattern 505a.

As shown in FIG. 4D, the hard mask pattern 520a optionally may be removed and a spacer layer may be formed on the gate electrode pattern 515a and the gate dielectric pattern 505a. The spacer layer may be formed using a deposition process (for example, CVD). The spacer layer may be etched to form a spacer 535a (for example, silicon nitride) on the sidewalls of the gate electrode pattern 515a and the gate dielectric pattern 505a. After the spacer 535a is formed, ions may be injected into the substrate 500 to form source/drain impurity regions (S/D).

As shown in FIG. 4E, an interlayer insulating film 560 (for example, oxide) covering the gate electrode pattern 515a, the gate dielectric pattern 505a, and the spacer 535a may be formed on the substrate 500. Thereafter, electrical contact portions 570a, 570b, and 570c connected to the gate electrode pattern 515a and the S/D regions may be formed in the interlayer insulating film 560. The electrical contact portions 570a, 570b, 570c may be formed of a conductive material (for example, metal). Although not shown, a barrier layer may be formed between the sidewall of the interlayer insulating film 560 and the electrical contact portions 570a, 570b, and 570c.

FIGS. 4A to 4E show an example of forming transistors, but the disclosure is not limited thereto.

For example, although not illustrated in FIGS. 4D and 4E, in some embodiments, the hard mask pattern 520a may not be removed before the spacer 535a is formed. For example, if the hard mask pattern 520a is not removed, then the hard mask pattern 520a may remain on top of the gate electrode 515a in FIGS. 4D and 4E, the spacer 535a may cover a sidewall of the hard mask pattern 520a in FIGS. 4D and 4E, and the electrical contact 570b may extend through an opening in the hard mask pattern 520a to directly contact an upper surface of the gate electrode 515a.

The resist composition according to an embodiment may be used in a patterning process for forming other types of semiconductor devices.

The disclosure will be described in more detail using the following examples and comparative examples, but the technical scope of the disclosure is not limited to the following examples.

### EXAMPLES

### Synthesis Example 1: Synthesis of Polymer HS/EAd

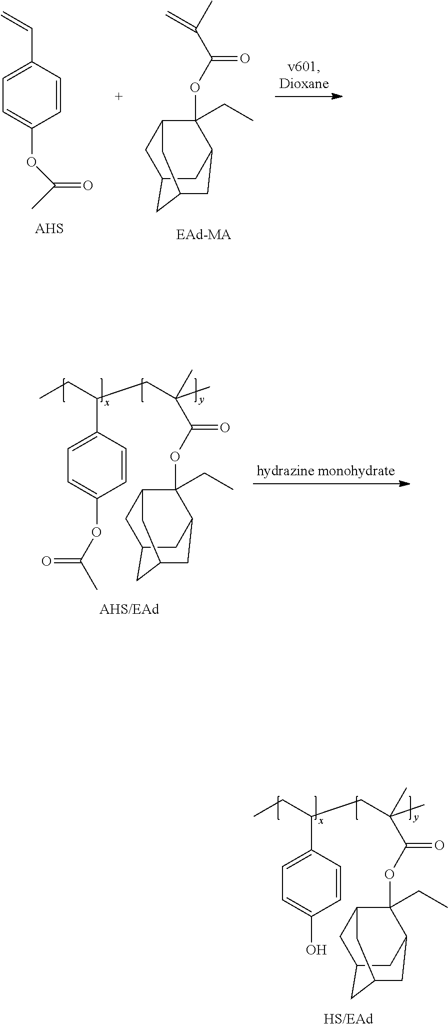

1.5 g (9.3 mmol) of acetoxystyrene (AHS), 2.3 g (9.3 mmol) of 2-ethyl-2-adamantyl methacrylate (EAd-MA), and 0.2 g (0.9 mmol) of an azo initiator V601 were dissolved in 18 mL of dioxane, and reacted at 80° C. for 4 hours to obtain AHS/EAd. 1 g of hydrazine monohydrate was added to AHS/EAd and reacted at room temperature for 2 hours to obtain a reaction product. Next, 50 mL of deionized water and 2 g of acetic acid was added to the reaction product, extracted with ethyl acetate (EA), and then precipitated in hexane to obtain a precipitate. Then, the precipitate was dried for 24 hours at 40° C. to obtain a polymer HS/EAd in the form of white powder. The obtained polymer HS/EAd has a number average molecular weight (Mn) of 4000 and a PDI of 1.3

### Evaluation Example 1: Evaluation of Acid Generation Effect

Acid generation effects were evaluated by the following method. Coumarin 6 (CAS No. 38215-36-0) was dissolved in acetonitrile (ACN) at a concentration of 6.5 wt %, and PAG was added in the same molar amount as Coumarin 6. Next, a solution obtained by adding the additives in the amounts described in Table 1 below was transferred to a quartz cell and exposed to DUV of a dose of 0 to 100 mj/cm², and then absorbance was measured. Theoretically, Coumarin 6 absorbs light at a wavelength of 460 nm. However, the absorbance of Coumarin 6 at a wavelength of 522 nm is increased by an acid, and thus Coumarin 6 was used as an acid indicator. After assuming that the absorbance intensity of Coumarin 6 after exposure to 100 mJ/cm² was 100% converted, the absorbance intensity thereof at each exposure dose was normalized to indicate degree of acid generation. At this time, the degree of acid generation was expressed as a relative value based on the value of Comparative Example 1-1.

TABLE 1

| | | | Photoacide | Degree of acid |
|---|---|---|---|---|
| | | | generator: | generation |
| | Photoacid | | additive | @ DUV 15 |
| | generator | Additive | (weight ratio) | mJ/cm² |
| Example 1-1 | PAG | A | 1:0.03 | 2500 |
| Example 1-2 | PAG | A | 1:0.17 | 1420 |
| Example 1-3 | PAG | A | 1:0.3 | 183 |
| Comparative | PAG | — | 1:0 | 100 |
| Example 1-1 | | | | |
| Comparative | PAG | B | 1:0.17 | 85 |
| Example 1-2 | | | | |
| Comparative | PAG | C | 1:0.17 | 101 |
| Example 1-3 | | | | |

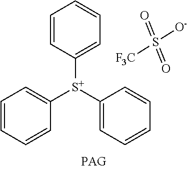 [SMILES: c1ccc([S+](c2ccccc2)c2ccccc2)cc1 ; O=S(=O)([O-])C(F)(F)F]

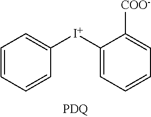

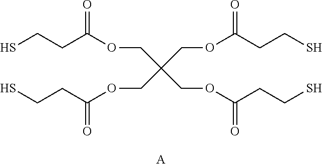

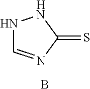

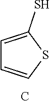

Referring to Table 1, it can be confirmed that Examples 1-1 to 1-3 have an improved acid generation effect compared to Comparative Examples 1-1 to 1-3. That is, when additives are used as in Examples 1-1 to 1-3, it can be expected that more improved resolution can be provided even when the same amount of photoacid generator is used.

### Evaluation Example 2: Thin Film Development Evaluation 1

The polymer HS/EAd synthesized in Synthesis Example 1 was dissolved to 1.6 wt % in a casting solvent of PGME/PGMEA=7/3 (w/w), and then 0.024 mmol of PAG and 0.016 mmol of PDQ were added. Then, additives were added thereto as shown in Table 2 below, and the resultant was filtered through a 0.2 μm membrane filter. The casting solution was spin-coated on a HMDS-treated silicon wafer at a speed of 1500 rpm, and then dried (PAB) at 110° C. for 1 minute to produce a film. Next, the film was exposed to EUV having a wavelength of 13.5 nm at a dose of 0 to 50 mJ/cm², post-exposure baked at 90° C. for 60 seconds, immersed in 2.38 wt % of a TMAH aqueous solution at 25° C. for 20 seconds, washed with deionized water for 10 seconds to remove a portion exposed to EUV and then dried to form a resist pattern. For the photoresist pattern, Eop, resolution, IPU, and sensitivity were measured using Critical Dimension Measurement Scanning Electron Microscope (CD-SEM), respectively.

A Z-factor was calculated by putting the measured value into Equation 1 below, and the results were normalized and shown in Table 2 below.

$$Z - factor = {( resolution )}^{3} \times {( IPU )}^{2} \times ( sensitivity ) \qquad < Equation 1 >$$

In Equation 1, resolution is a CD size (half pitch), IPU is a value calculated from the distribution of CD, and sensitivity is Eop (dose). The lower the Z-factor, the better the pattern performance at the same dose.

TABLE 2

| | | | Additive | | |
|---|---|---|---|---|---|
| | Photoacid | | content | | Eₒₚ |
| | generator | Additive | (wt %) | Z-factor | (mJ/cm²) |
| Example 2-1 | PAG | A | 10 | 3.68 × 10⁻⁸ | 17.4 |
| Example 2-2 | PAG | A | 5 | 3.00 x 10⁻⁸ | 25.6 |
| Example 2-3 | PAG | A | 2 | 2.95 × 10⁻⁸ | 29.9 |
| Comparative | PAG | — | 0 | 3.15 x 10⁻⁸ | 37 |
| Example 2-1 | | | | | |
| Comparative | PAG | B | 2 | 4.20 x 10⁻⁸ | 42.2 |
| Example 2-2 | | | | | |
| Comparative | PAG | C | 2 | 3.32 × 10⁻⁸ | 37.2 |
| Example 2-3 | | | | | |

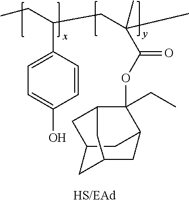

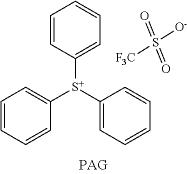 [SMILES: c1ccc([S+](c2ccccc2)c2ccccc2)cc1 ; O=S(=O)([O-])C(F)(F)F]

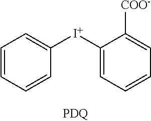

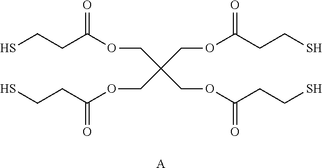

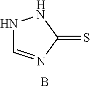

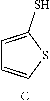

Referring to Table 2, it can be confirmed that the Z-Factor and/or Eₒₚ of the photoresist patterns applied with the photoresist films formed from the photoresist compositions of Examples 2-1 to 2-3 are low compared to those of the photoresist patterns applied with the photoresist films formed from the photoresist compositions of Comparative Examples 2-1 to 2-3.

### Evaluation Example 3: Thin Film Development Evaluation 2

76 mg of the polymer HS/EAd synthesized in Synthesis Example 1, 23.13 mg of PAG, and 10.54 mg of PDQ were added to a casting solvent of PGME/PGMEA=7/3 (w/w). Then, additives were added thereto as shown in Tables 3 and 4 below, and the resultant was filtered through a 0.2 μm membrane filter. The casting solution was spin-coated on a HMDS-treated silicon wafer at a speed of 1500 rpm, and then dried (PAB) at 110° C. for 1 minute to produce a film. Next, the film was exposed to DUV having a wavelength of 248 nm or EUV having a wavelength of 13.5 nm at a dose of 0 to 50 mJ/cm², post-exposure baked at 90° C. for 60 seconds, immersed in 2.38 wt % of a TMAH aqueous solution at 25° C. for 20 seconds, washed with deionized water for 10 seconds to remove a portion exposed to EUV and then dried to form a resist pattern. The thickness of the film remaining on the photoresist pattern was measured using a three-dimensional optical profiler (Bruker, Contour X-100), and E₀ and E₁ were measured, respectively. The results are shown in Tables 3 and 4 below. Table 3 shows data by DUV, and Table 4 shows data by EUV.

E₀ refers to the exposure amount at the point where the thin film is completely developed (the thickness of the thin film no longer decreases), and E₁ refers to the exposure amount at the point where the thin film begins to develop. γ is a value calculated from Contrast Curve by Equation 2 below.

$$γ = {[ log ( \frac{{E}_{0}}{{E}_{1}} ) ]}^{- 1} \qquad < Equation 2 >$$

TABLE 3

| | | | Additive | | | |
|---|---|---|---|---|---|---|
| | | | content | | | |
| | | | (wt % with | | | |
| | | Additive | respect to | E₁ | E₀ | |
| | Addi- | content | polymer | (mJ/ | (mJ/ | |
| | tive | (mg) | HS/EAd) | cm²) | cm²) | g |
| Example 3-1 | A | 15.2 | 20 | 5 | 10 | 3.3 |
| Example 3-2 | A | 7.6 | 10 | 5 | 10 | 3.3 |
| Comparative | — | 0 | 0 | 10 | 15 | 5.7 |
| Example 3-1 | | | | | | |
| Comparative | B | 7.6 | 10 | 10 | 20 | 3.3 |
| Example 3-2 | | | | | | |
| Comparative | C | 7.6 | 10 | 10 | 20 | 3.3 |
| Example 3-3 | | | | | | |

TABLE 4

| | | | Additive | | | |
|---|---|---|---|---|---|---|
| | | | content | | | |
| | | | (wt % with | | | |
| | | Additive | respect to | | | |
| | | content | polymer | E₁ | E₀ | |
| | Additive | (mg) | HS/EAd) | (mJ/cm²) | (mJ/cm²) | Y |
| Example 4- | A | 15.2 | 20 | 5 | 8 | 4.9 |
| 1 | | | | | | |
| Example 4- | A | 7.6 | 10 | 5 | 11 | 2.9 |
| 2 | | | | | | |
| Comparative | — | 0 | 0 | 5 | 19 | 1.7 |
| Example | | | | | | |
| 4-1 | | | | | | |
| Comparative | B | 7.6 | 10 | 5 | 25 | 1.4 |
| Example | | | | | | |
| 4-2 | | | | | | |
| Comparative | C | 7.6 | 10 | 5 | 20 | 1.7 |
| Example | | | | | | |
| 4-3 | | | | | | |

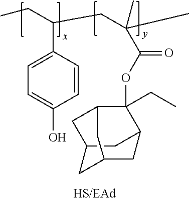

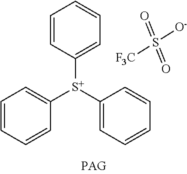 [SMILES: c1ccc([S+](c2ccccc2)c2ccccc2)cc1 ; O=S(=O)([O-])C(F)(F)F]

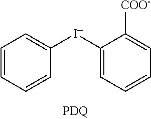

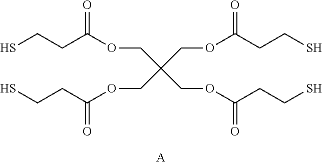

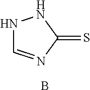

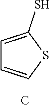

Referring to Table 3, it can be confirmed that Examples 3-1 and 3-2 show smaller E₁ values and smaller E₀ values than Comparative Examples 3-1 to 3-3, which suggests that Examples 3-1 and 3-2 have improved sensitivity compared to Comparative Examples 3-1 to 3-3.

Referring to Table 4, it can be confirmed that Examples 4-1 and 4-2 show larger γ values than Comparative Examples 4-1 to 4-3, which suggests that Examples 4-1 and 4-2 have improved sensitivity compared to Comparative Examples 4-1 to 4-3.

According to the embodiments, a resist composition having improved sensitivity, improved resolution, and/or reduced defects can be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A resist composition comprising:
a polymer including a first repeating unit represented by Formula 1 and not including a crosslinking group; and
an additive represented by Formula 2, 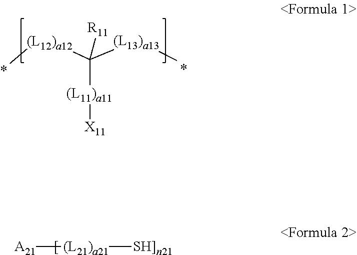
wherein, in Formulae 1 and 2,
L₁₁ to L₁₃ are each independently a single bond, O, S, C(═O), C(═O)O, OC(═O), C(═O)NR₁₂, NR₁₂C(═O), S(═O), S(═O)₂, S(═O)₂O, OS(═O)₂, or a linear, branched, or cyclic C₁-C₃₀ divalent hydrocarbon group which optionally includes a heteroatom,
a11 to a13 are each independently an integer from 1 to 4,
R₁₁ and R₁₂ are each independently hydrogen, deuterium, a halogen, a cyano group, a hydroxyl group, an amino group, a carboxylic acid group, a thiol group, an ester moiety, a sulfonate ester moiety, a carbonate moiety, a lactone moiety, a sultone moiety, a carboxylic anhydride moiety, or a linear, branched, or cyclic C₁-C₃₀ monovalent hydrocarbon group which optionally includes a heteroatom,
X₁₁ is an acid labile group,
A₂₁ is a substituted or unsubstituted carbon atom, a substituted or unsubstituted C₁-C₃₀ alkyl group, a substituted or unsubstituted C₃-C₃₀ cycloalkyl group, a substituted or unsubstituted C₁-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₁-C₃₀ heterocycloalkenyl group, a substituted or unsubstituted C₂-C₃₀ alkynyl group, a substituted or unsubstituted C₁-C₃₀ aryl group, or a substituted or unsubstituted C₁-C₃₀ heteroaryl group,
when A₂₁ is the substituted or unsubstituted C₁-C₃₀ heterocycloalkyl group, the substituted or unsubstituted C₁-C₃₀ heterocycloalkenyl group, or the substituted or unsubstituted C₁-C₃₀ heteroaryl group, A₂₁ does not include nitrogen (N) or sulfur (S) as a ring source in the substituted or unsubstituted C₁-C₃₀ heterocycloalkyl group, the substituted or unsubstituted C₁-C₃₀ heterocycloalkenyl group, or the substituted or unsubstituted C₁-C₃₀ heteroaryl group,
L₂₁ is a single bond, O, S, C(═O), C(═O)O, OC(═O), C(═O)NR₂₁, NR₂₁C(═O), S(═O), S(═O)₂, S(═O)₂O, OS(═O)₂, or a linear, branched, or cyclic C₁-C₃₀ divalent hydrocarbon group which optionally includes a heteroatom,
a21 is an integer from 1 to 4,
R₂₁ is hydrogen, deuterium, a halogen, a cyano group, a hydroxyl group, an amino group, a carboxylic acid group, a thiol group, an ester moiety, a sulfonate ester moiety, a carbonate moiety, a lactone moiety, a sultone moiety, a carboxylic anhydride moiety, or a C₁-C₃₀ linear, branched, or cyclic monovalent hydrocarbon group which optionally includes a heteroatom,
n21 is an integer from 1 to 8, and
* is a bonding site with a neighboring atom.

2. The resist composition of claim 1, wherein
L₁₁ to L₁₃ are each independently a single bond, O, S, C(═O), C(═O)O, OC(═O), C(═O)NH, NHC(═O), S(═O), S(═O)₂, S(═O)₂O, OS(═O)₂, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

3. The resist composition of claim 1, wherein
R₁₁ is selected from: hydrogen; deuterium; a halogen; a cyano group; hydroxyl group; an amino group; a carboxylic acid group; a thiol group; and a C₁-C₂₀ alkyl group, a C₃-C₂₀ cycloalkyl group, and a C₆-C₂₀ aryl group, each unsubstituted or substituted with deuterium, a halogen, a cyano group, a hydroxyl group, an amino group, a carboxylic acid group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

4. The resist composition of claim 1, wherein
X₁₁ is represented by any one of Formulae 6-1 to 6-11: 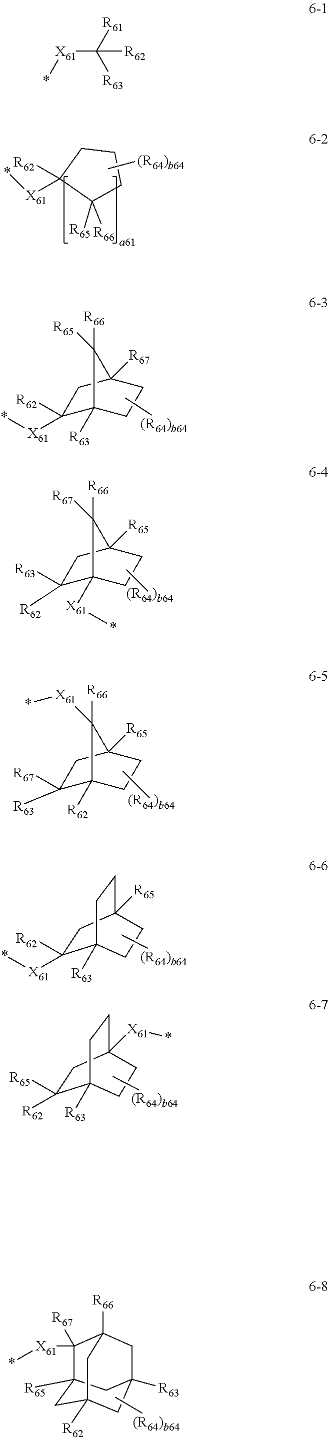 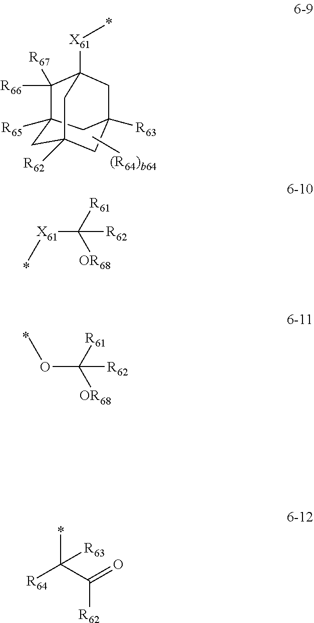
in Formulae 6-1 to 6-11,
X₆₁ is an ester moiety, a sulfonate moiety, a carbonate moiety, or a carbamate moiety,
a61 is an integer from 0 to 6,
R₆₁ and R₆₈ are each independently a linear, branched, or cyclic C₁-C₂₀ monovalent hydrocarbon group which optionally includes a heteroatom,
R₆₂ to R₆₇ are each independently hydrogen, deuterium, a halogen, a cyano group, a hydroxyl group, an amino group, a carboxylic acid group, a thiol group, an ester moiety, a sulfonate ester moiety, a carbonate moiety, a carbamate moiety, a lactone moiety, a sultone moiety, a carboxylic anhydride moiety, or a linear, branched, or cyclic C₁-C₃₀ monovalent hydrocarbon group that optionally includes a heteroatom,
two adjacent groups of R₆₁ to R₆₈ are selectively combined with each other to form a ring,
b64 is an integer from 1 to 10, and
* is a bonding site with a neighboring atom.

5. The resist composition of claim 1, wherein
the first repeating unit is selected from Group I:

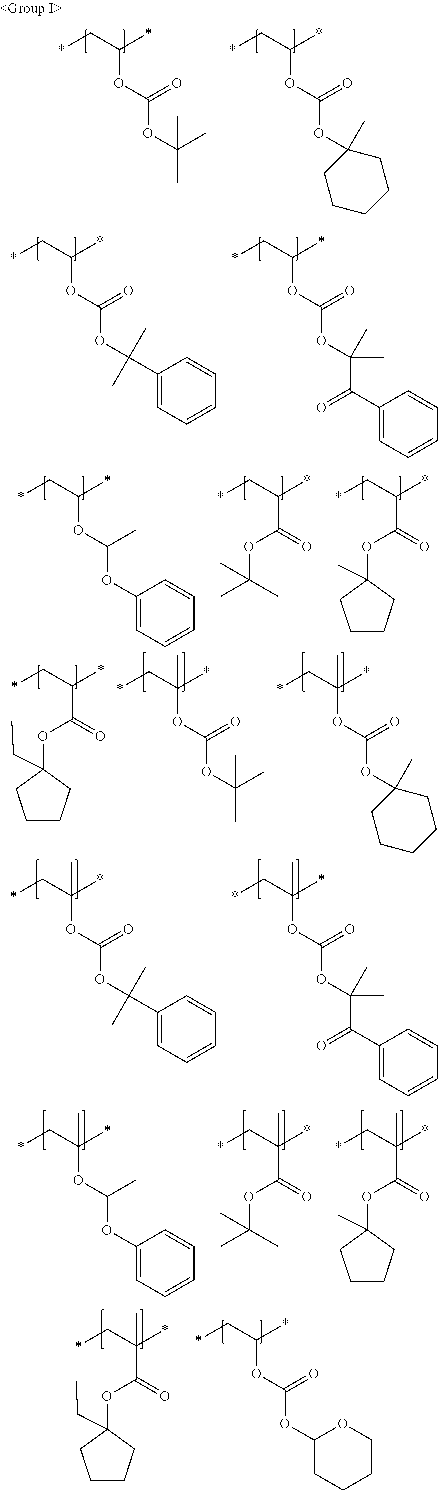

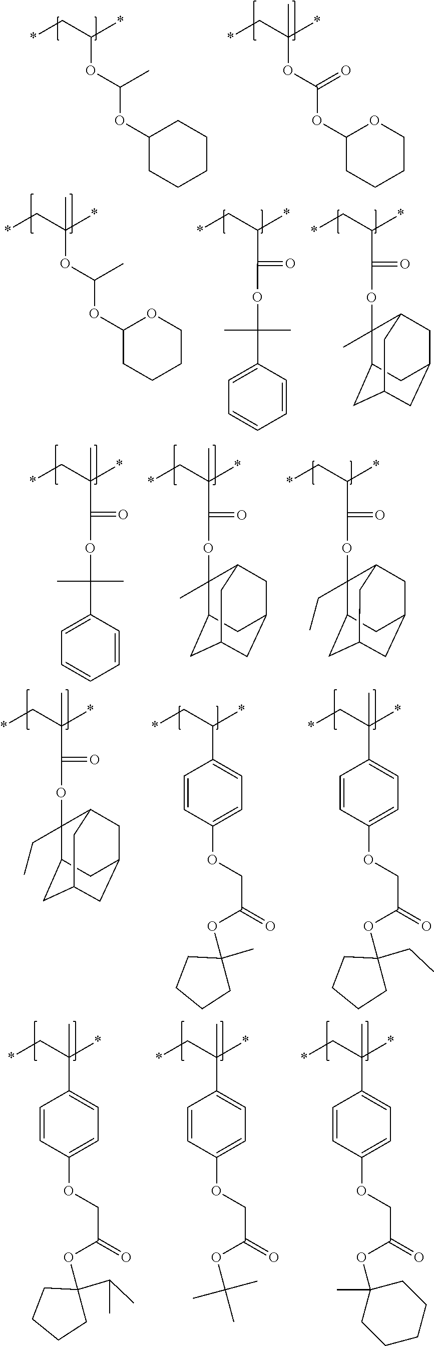

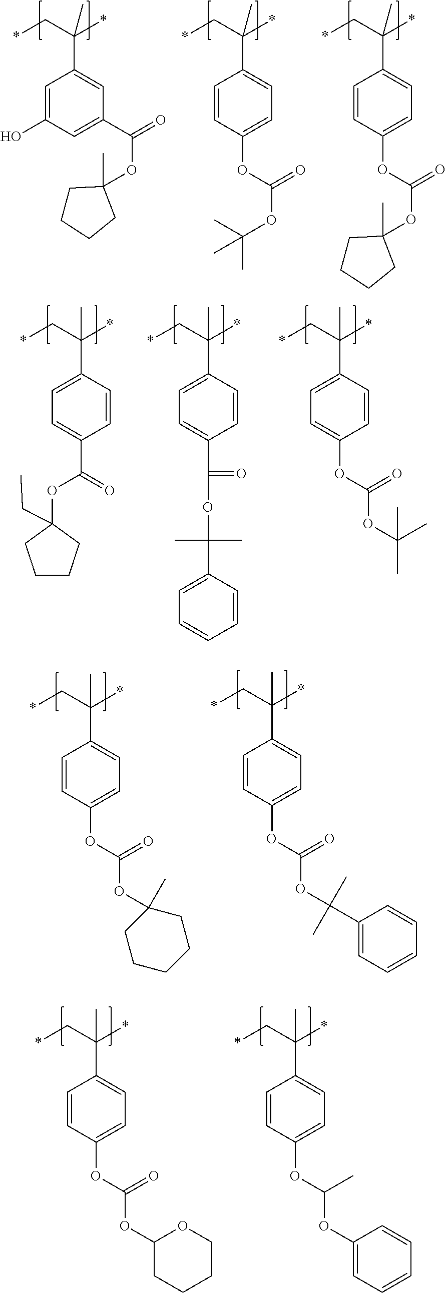

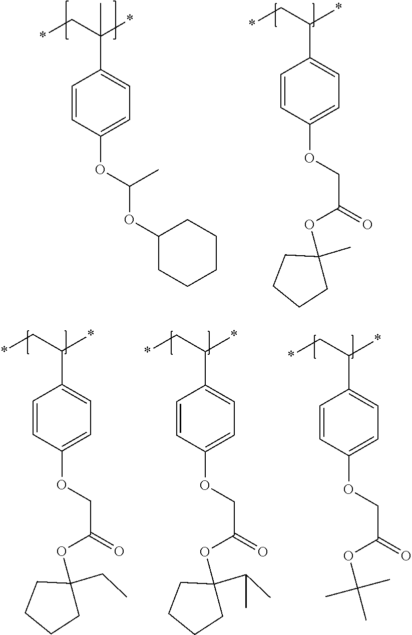

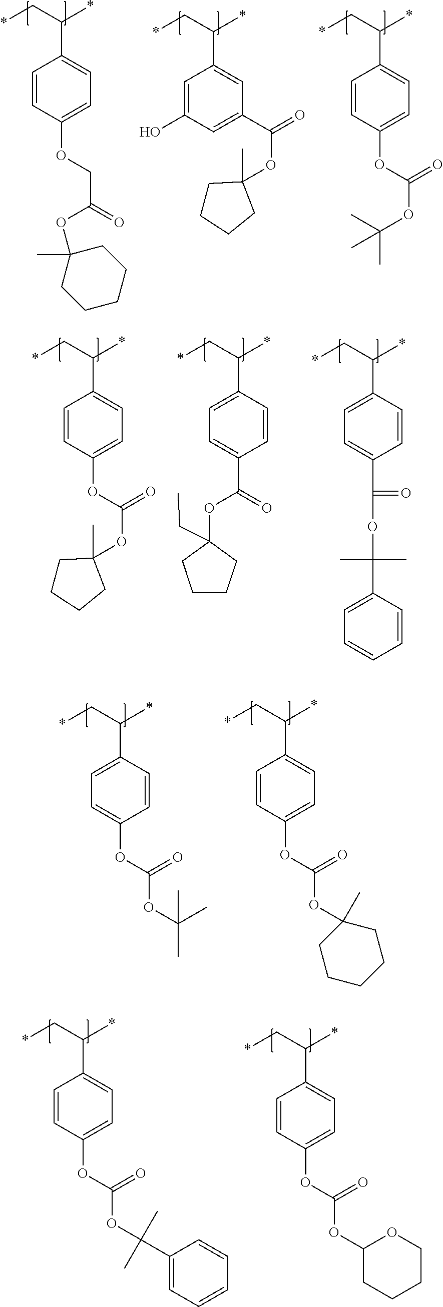

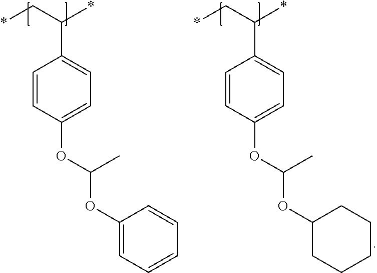

6. The resist composition of claim 1, further comprising:
a second repeating unit represented by Formula 3: 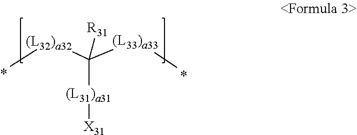
in Formula 3,
L₃₁ to L₃₃ are each independently a single bond, O, S, C(═O), C(═O)O, OC(═O), C(═O)NR₃₂, NR₃₂C(═O), S(═O), S(═O)₂, S(═O)₂O, OS(═O)₂, or a linear, branched, or cyclic C₁-C₃₀ divalent hydrocarbon group which optionally includes a heteroatom,
a31 to a33 are each independently an integer from 1 to 4,
R₃₁ and R₃₂ are each independently hydrogen, deuterium, a halogen, a cyano group, a hydroxyl group, an amino group, a carboxylic acid group, a thiol group, an ester moiety, a sulfonate ester moiety, a carbonate moiety, a lactone moiety, a sultone moiety, a carboxylic anhydride moiety, or a linear, branched, or cyclic C₁-C₃₀ monovalent hydrocarbon group which optionally include a heteroatom,
X₃₁ is a non-acid labile group, and
* is a bonding site with a neighboring atom.

7. The resist composition of claim 6, wherein
X₃₁ is selected from hydrogen, a hydroxyl group, and groups represented by Formulae 5-1 to 5-16: 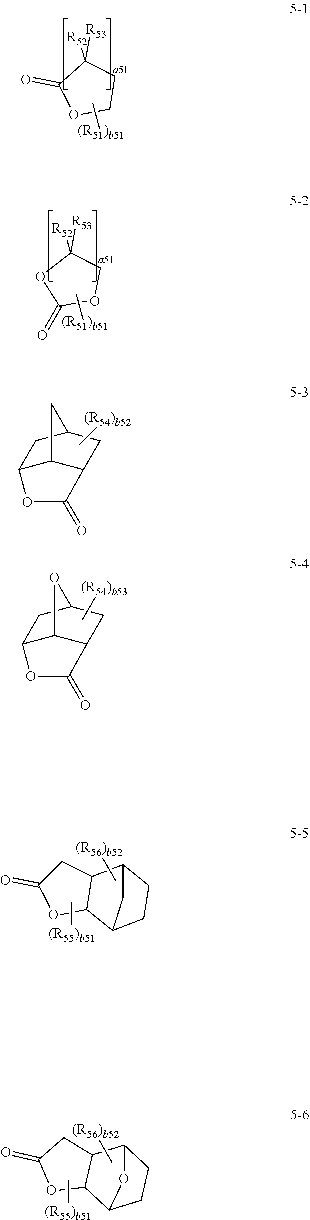 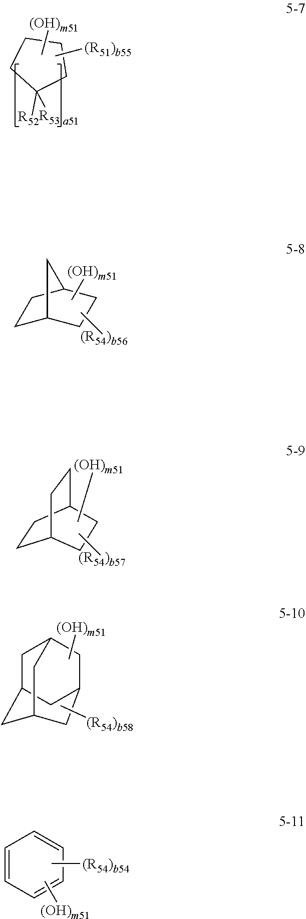 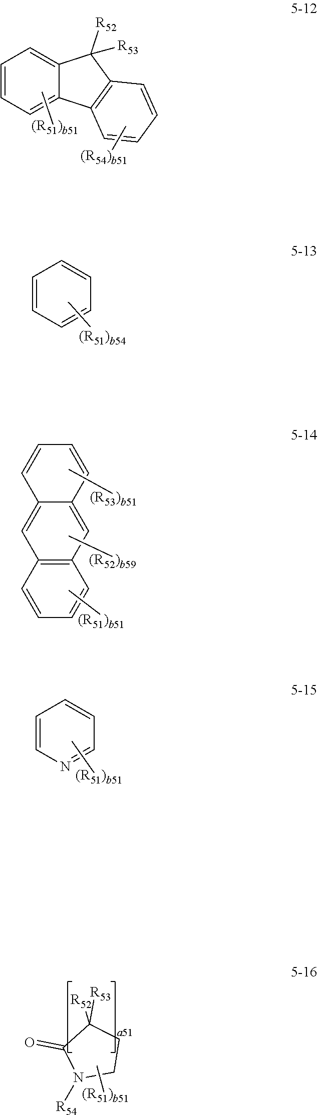
in Formulae 5-1 to 5-16,
a51 is 1 or 2,
R₅₁ to R₅₆ are each independently a bonding site with a neighboring atom, hydrogen, deuterium, a halogen, a cyano group, a hydroxyl group, an amino group, a carboxylic acid group, a thiol group, an ester moiety, a sulfonate ester moiety, a carbonate moiety, a carbamate moiety, a lactone moiety, a sultone moiety, a carboxylic anhydride moiety, or a linear, branched, or cyclic C₁-C₃₀ monovalent hydrocarbon group which optionally includes a heteroatom,
one of R₅₁ to R₅₃, one of R₅₄, and one of R₅₅ and R₅₆ are each a bonding site with a neighboring atom,
b51 is an integer from 1 to 4,
b52 is an integer from 1 to 10,
b53 is an integer from of 1 to 8,
b54 is an integer from of 1 to 5,
b55 is an integer from of 1 to 7,
b56 is an integer from of 1 to 11,
b57 is an integer from 1 to 13,
b58 is an integer from 1 to 15,
b59 is an integer from 1 to 2, and
m51 is an integer from 1 to 4.

8. The resist composition of claim 6, wherein
X₃₁ is selected from a hydroxyl group, and the group represented by Formula 5-11.

9. The resist composition of claim 6, wherein
the second repeating unit is selected from Group II:

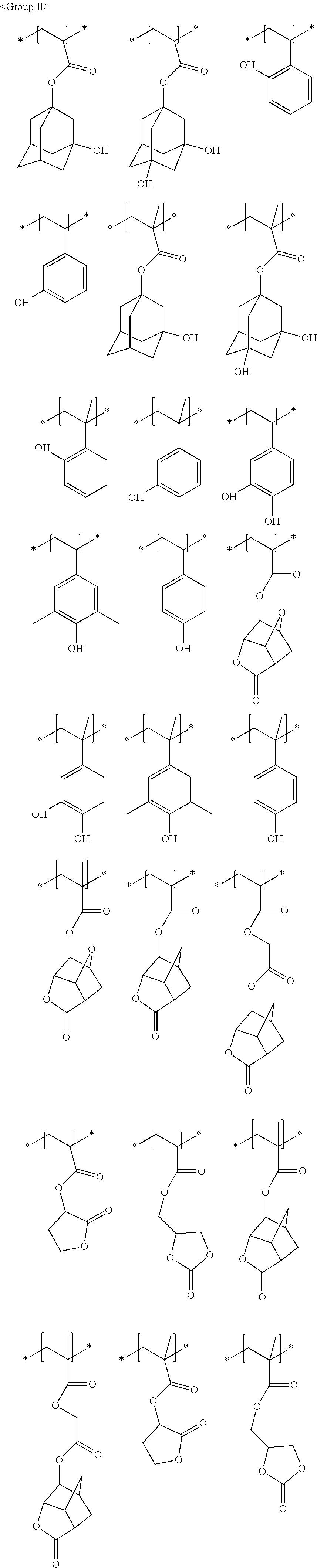

10. The resist composition of claim 1, wherein
A₂₁ is a substituted or unsubstituted carbon atom, a substituted or unsubstituted C₁-C₃₀ alkyl group, a substituted or unsubstituted C₃-C₃₀ cycloalkyl group, a substituted or unsubstituted C₁-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₁-C₃₀ heterocycloalkenyl group, a substituted or unsubstituted C₂-C₃₀ alkynyl group, a substituted or unsubstituted C₁-C₃₀ aryl group, or a substituted or unsubstituted C₁-C₃₀ heteroaryl group, and
when A₂₁ is the substituted or unsubstituted C₁-C₃₀ heterocycloalkyl group, the substituted or unsubstituted C₁-C₃₀ heterocycloalkenyl group, or the substituted or unsubstituted C₁-C₃₀ heteroaryl group, A₂₁ includes oxygen (O), selenium (Se) or phosphorus (P) as a heteroatom constituting a ring in the substituted or unsubstituted C₁-C₃₀ heterocycloalkyl group, the substituted or unsubstituted C₁-C₃₀ heterocycloalkenyl group, or the substituted or unsubstituted C₁-C₃₀ heteroaryl group.

11. The resist composition of claim 1, wherein
A₂₁ is a substituted or unsubstituted carbon atom, a substituted or unsubstituted C₁-C₃₀ alkyl group, a substituted or unsubstituted C₃-C₃₀ cycloalkyl group, a substituted or unsubstituted C₂-C₃₀ alkenyl group, a substituted or unsubstituted C₃-C₃₀ cycloalkenyl group, a substituted or unsubstituted C₂-C₃₀ alkynyl group, or a substituted or unsubstituted C₁-C₃₀ aryl group.

12. The resist composition of claim 1, wherein
L₂₁ is a single bond, O, C(═O), C(═O)O, OC(═O), a substituted or unsubstituted C₁-C₃₀ alkylene group, a substituted or unsubstituted C₃-C₃₀ cycloalkylene group, a substituted or unsubstituted C₂-C₃₀ alkenylene group, a substituted or unsubstituted C₃-C₃₀ cycloalkenylene group, or a substituted or unsubstituted C₆-C₃₀ arylene group.

13. The resist composition of claim 1, wherein
n21 is an integer from 1 to 6.

14. The resist composition of claim 1, wherein
the additive is selected from Group 11:

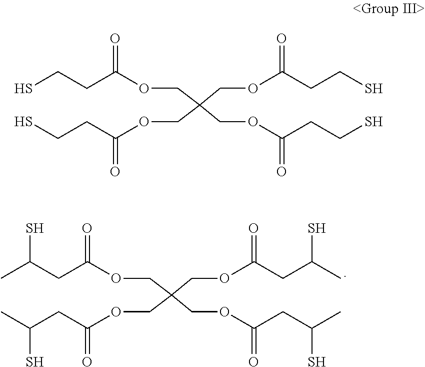 [SMILES: O=C(CCS)OCC(COC(=O)CCS)(COC(=O)CCS)COC(=O)CCS ; CC(S)CC(=O)OCC(COC(=O)CC(C)S)(COC(=O)CC(C)S)COC(=O)CC(C)S]

15. The resist composition of claim 1, wherein
the additive is included in an amount of about 0.01 parts by weight to about 50 parts by weight, based on 100 parts by weight of the polymer.

16. The resist composition of claim 1, further comprising
a photoacid generator.

17. The resist composition of claim 16, wherein
the additive is included in an amount of about 0.01 parts by weight to about 70 parts by weight, based on 100 parts by weight of the photoacid generator.

18. A method of forming a pattern, the method comprising:
forming a resist film by applying the resist composition of claim 1 onto a substrate;
exposing at least a portion of the resist film to high-energy rays to provide an exposed resist film; and
developing the exposed resist film using a developer.

19. The method of claim 18, wherein
the exposing is performed by irradiating the resist film using at least one of ultraviolet rays, deep ultraviolet (DUV) rays, extreme ultraviolet (EUV) rays, X-rays, γ-rays, electron beams (EBs), and α-rays.

20. The method of claim 18, wherein
the exposed resist film includes an exposed portion and a non-exposed portion, and
the exposed portion is removed in the developing the exposed resist film.
